(19) United States
(12) Patent Application Publication
(10) Pub. No.: US 2025/0031436 A1
(43) Pub. Date: Jan. 23, 2025

(54) STRUCTURE AND FORMATION METHOD OF SEMICONDUCTOR DEVICE WITH SEMICONDUCTOR NANOSTRUCTURES

(71) Applicant: Taiwan Semiconductor Manufacturing Company, Ltd., Hsinchu (TW)

(72) Inventors: Wei-Chih HOU, Hsinchu City (TW); Feng-Ming CHANG, Taitung City (TW); Chun-Jun LIN, Hsinchu City (TW); Kao-Ting LAI, Hsinchu City (TW); Jhon-Jhy LIAW, Zhudong Township (TW)

(73) Assignee: Taiwan Semiconductor Manufacturing Company, Ltd., Hsinchu (TW)

(21) Appl. No.: 18/355,999

(22) Filed: Jul. 20, 2023

(51) Int. Cl. H01L 21/8238; H01L 27/092; H01L 29/06; H01L 29/423; H01L 29/66; H01L 29/775

(52) U.S. Cl. CPC H01L 21/823807; H01L 21/823814; H01L 21/823842; H01L 27/092; H01L 29/0673; H01L 29/42392; H01L 29/66553; H01L 29/775

(57) ABSTRACT

A method for forming a semiconductor device structure is provided. The method includes forming a first fin structure and a second fin structure. Each of the first fin structure and the second fin structure has multiple sacrificial layers and multiple semiconductor layers laid out in an alternating manner, and the first fin structure is substantially as wide as the second fin structure. The method also includes forming a gate stack wrapped around the first fin structure and the second fin structure. The method further includes simultaneously removing the sacrificial layers of the first fin structure and the second fin structure. Remaining portions of the semiconductor layers of the first fin structure form multiple first semiconductor nanostructures, and remaining portions of the semiconductor layers of the second fin structure form multiple second semiconductor nanostructures. Each of the first semiconductor nanostructures is thicker than each of the second semiconductor nanostructures.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view of a semiconductor device structure, in accordance with some embodiments.

FIGS. 2A-2B are top views of various stages of a process for forming portions of a semiconductor device structure, in accordance with some embodiments.

FIGS. 3A-3G are cross-sectional views of various stages of a process for forming portions of a semiconductor device structure, in accordance with some embodiments.

FIGS. 4A-4L are cross-sectional views of various stages of a process for forming portions of a semiconductor device structure, in accordance with some embodiments.

FIGS. 5A-5L are cross-sectional views of various stages of a process for forming portions of a semiconductor device structure, in accordance with some embodiments.

FIGS. 6A-6B are cross-sectional views of various stages of a process for forming portions of a semiconductor device structure, in accordance with some embodiments.

FIG. 7 is a cross-sectional view of portions of a semiconductor device structure, in accordance with some embodiments.

FIG. 8 is a cross-sectional view of portions of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100% of what is specified. Furthermore, terms such as “substantially parallel” or “substantially perpendicular” are to be interpreted as not to exclude insignificant deviation from the specified arrangement and may include for example deviations of up to 10 degrees in some embodiments. The word “substantially” does not exclude “completely” e.g. a composition which is “substantially free” from Y may be completely free from Y in some embodiments.

Terms such as “about” in conjunction with a specific distance or size are to be interpreted so as not to exclude insignificant deviation from the specified distance or size and may include for example deviations of up to 10% of what is specified in some embodiments. The term “about” in relation to a numerical value x may mean x±5 or 10% of what is specified in some embodiments.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

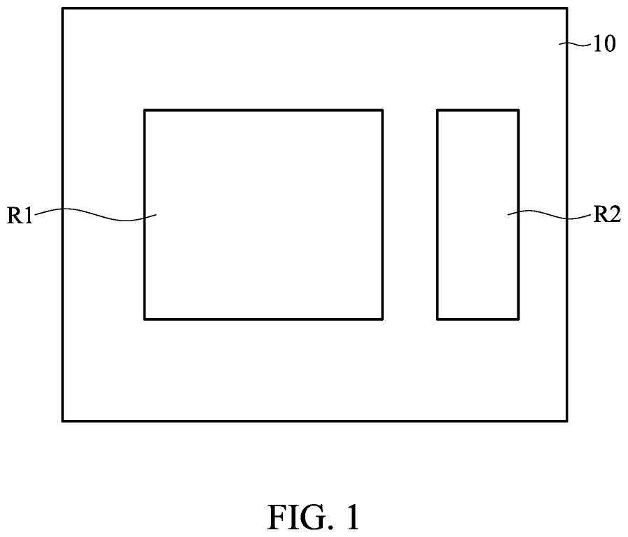

FIG. 1 is a top view of a semiconductor device structure 10, in accordance with some embodiments. The semiconductor device structure 10 may be a semiconductor chip. The semiconductor device structure 10 has a first region R1 and a second region R2, as shown in FIG. 1. In some embodiments, the firs region R1 includes multiple low power devices, and the second region R2 includes multiple high performance devices. In some embodiments, the low power devices in the first region R1 are formed to have reduced drain-induced barrier lowering (DIBL) issues. In some embodiments, the high performance devices in the second region R2 are formed to have higher drive current.

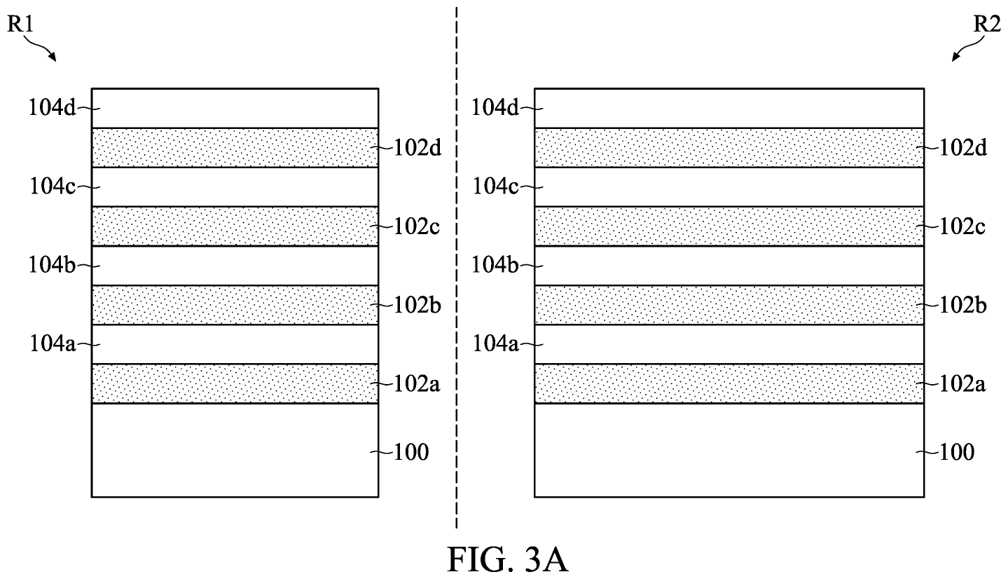

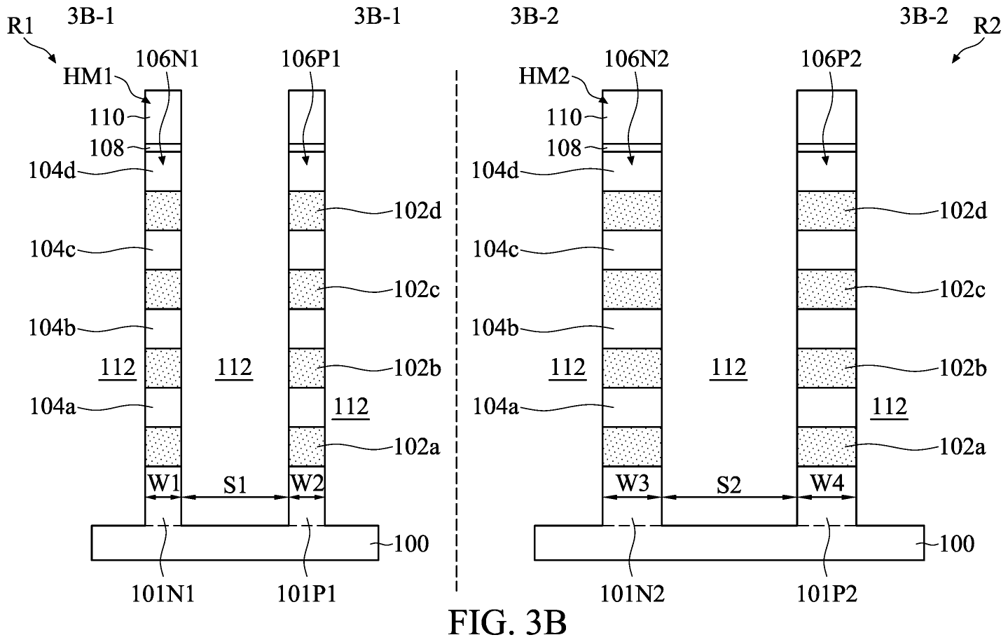

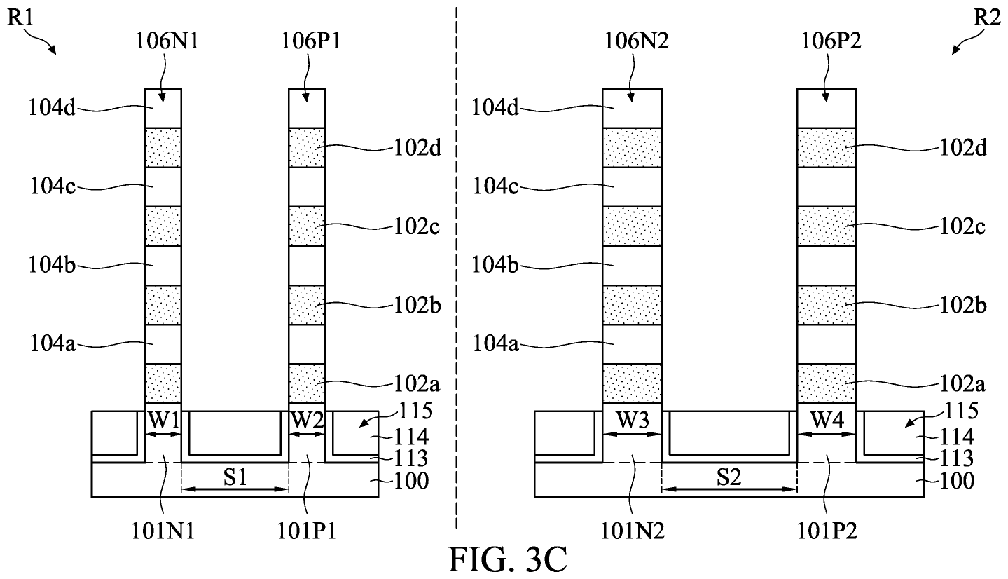

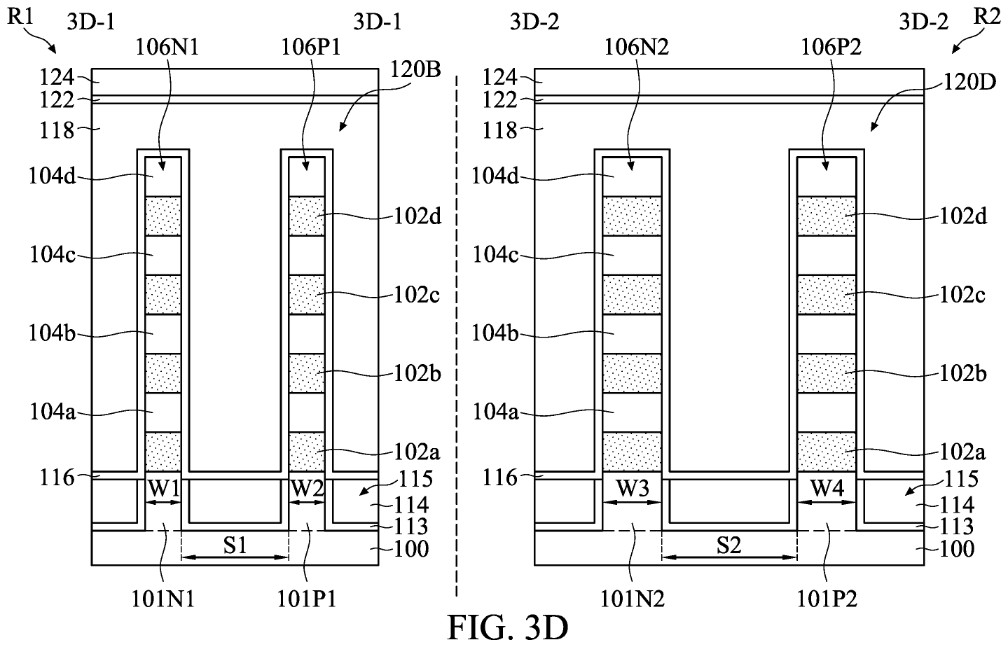

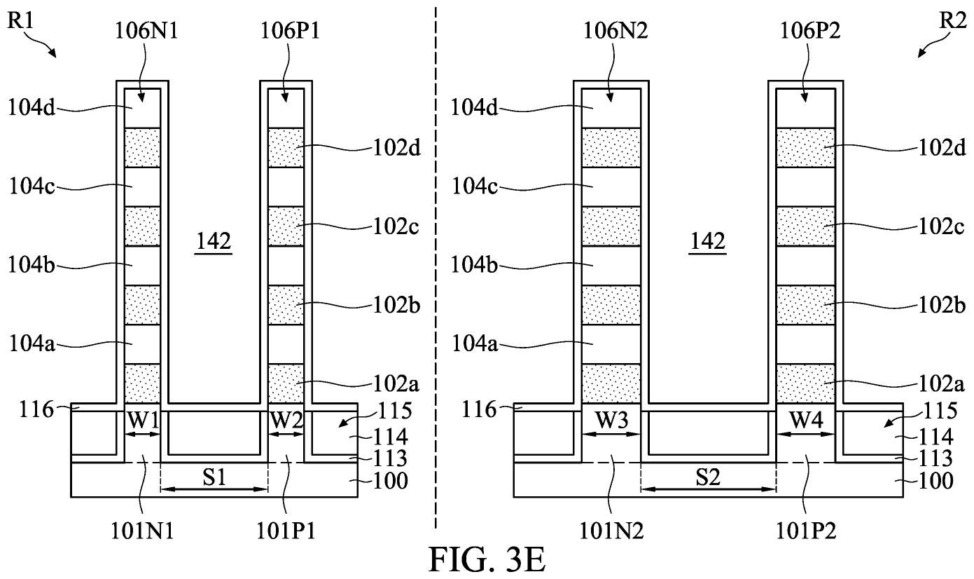

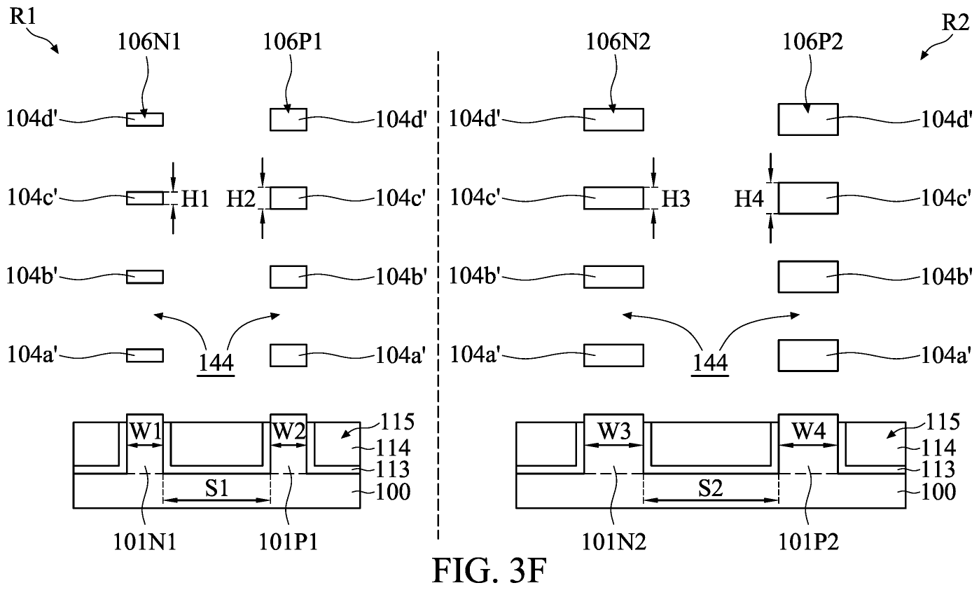

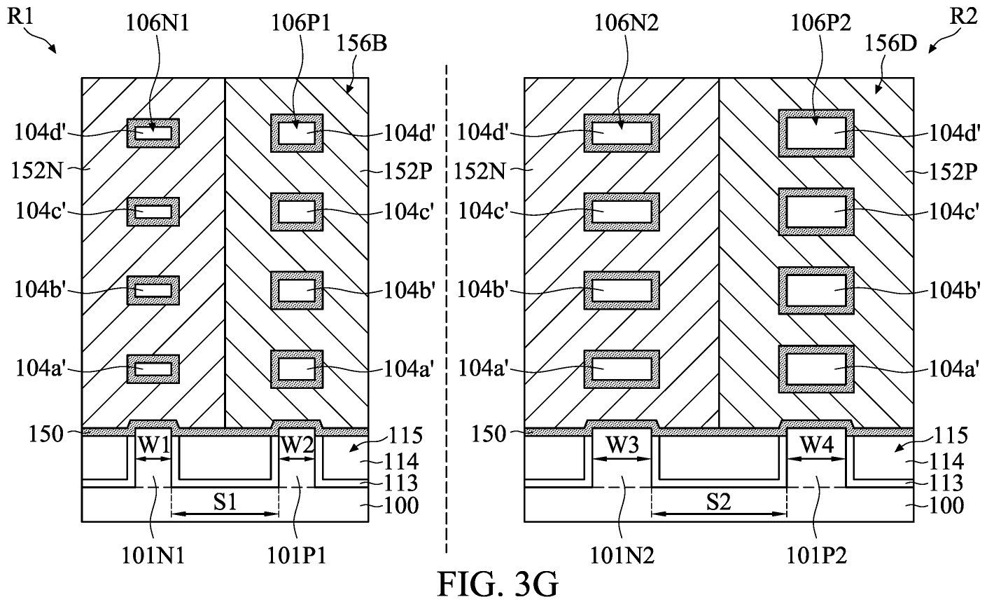

FIGS. 3A-3G are cross-sectional views of various stages of a process for forming a portion of a semiconductor device structure, in accordance with some embodiments. As shown in FIG. 3A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof).

In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 3A, a semiconductor stack having multiple semiconductor layers is formed over the semiconductor substrate 100, in accordance with some embodiments. In FIG. 3A, the left side shows a portion of the semiconductor device structure formed in the first region R1, and the right side shows a portion of the semiconductor device structure formed in the second region R2.

In some embodiments, the semiconductor stack includes multiple sacrificial layers 102a, 102b, 102c, and 102d. The semiconductor stack also includes multiple semiconductor layers 104a, 104b, 104c, and 104d. In some embodiments, the sacrificial layers 102a-102d and the semiconductor layers 104a-104d are laid out in an alternating manner, as shown in FIG. 3A.

In some embodiments, the sacrificial layers 102a-102d will be removed in a subsequent process to release the semiconductor layers 104a-104d. The semiconductor layers 104a-104d that are released may be formed into semiconductor nanostructures. The semiconductor nanostructures may function as channel structures of one or more transistors.

In some embodiments, the semiconductor layers 104a-104d that will be used to form channel structures are made of a material that is different than that of the sacrificial layers 102a-102d. In some embodiments, the semiconductor layers 104a-104d are made of or include silicon, germanium, another suitable material, or a combination thereof. In some embodiments, the sacrificial layers 102a-102d are made of or include silicon germanium or another suitable material.

In some other embodiments, the semiconductor layers 104a-104d are made of silicon germanium, and the sacrificial layers 102a-102d are made of silicon germanium with different atomic concentration of germanium than that of the semiconductor layers 104a-104d.

Due to the different compositions, different etching selectivity and/or different oxidation rates during subsequent processing may be achieved between the sacrificial layers 102a-102d and the semiconductor layers 104a-104d.

The present disclosure contemplates that the sacrificial layers 102a-102d and the semiconductor layers 104a-104d include any combination of materials that can provide desired etching selectivity, desired oxidation rate differences, and/or desired performance characteristics (e.g., materials that increase current flow).

In some embodiments, the sacrificial layers 102a-102d and the semiconductor layers 104a-104d are formed using multiple epitaxial growth operations. Each of the sacrificial layers 102a-102d and the semiconductor layers 104a-104d may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof.

In some embodiments, the sacrificial layers 102a-102d and the semiconductor layers 104a-104d are grown in-situ in the same process chamber. In some embodiments, the growth of the sacrificial layers 102a-102d and the semiconductor layers 104a-104d are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements HM1 and HM2 are formed over the semiconductor stack to assist in a subsequent patterning of the semiconductor stack. In some embodiments, each of the hard mask elements HM2 is wider than each of the hard mask elements HM1, as shown in FIG. 3B. Each of the hard mask elements HM1 and HM2 may include a first mask layer 108 and a second mask layer 110. The first mask layer 108 and the second mask layer 110 may be made of different materials. One or more photolithography processes may be used to form the hard mask elements HM1 and HM2.

As shown in FIG. 3B, with the hard mask elements HM1 and HM2 as an etching mask, the semiconductor stack is patterned to form multiple fin structures 106N1, 106P1, 106N2, and 106P2, in accordance with some embodiments. One or more etching processes are used to pattern the semiconductor stack into the fin structures 106N1, 106P1, 106N2, and 106P2. The fin structures 106N1, 106P1, 106N2, and 106P2 may be patterned by any suitable method.

For example, the fin structures 106N1, 106P1, 106N2, and 106P2 may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures (including fin structures 106N1, 106P1, 106N2, and 106P2) and multiple trenches 112, as shown in FIG. 3B. Each of the fin structures 106N1, 106P1, 106N2, and 106P2 may include portions of the sacrificial layers 102a-102d and the semiconductor layers 104a-104d and multiple semiconductor fins (including semiconductor fins 101N1, 101P1, 101N2, and 101P2), as shown in FIG. 3B. The semiconductor substrate 100 may also be partially removed during the etching process that forms the fin structures. Protruding portions of the semiconductor substrate 100 that remain form the semiconductor fins 101N1, 101P1, 101N2, and 101P2.

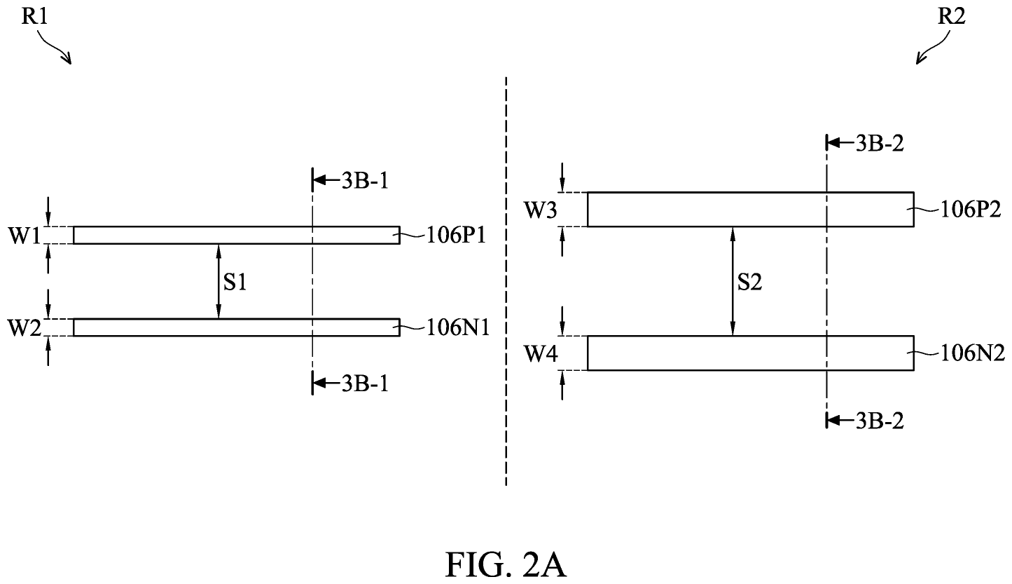

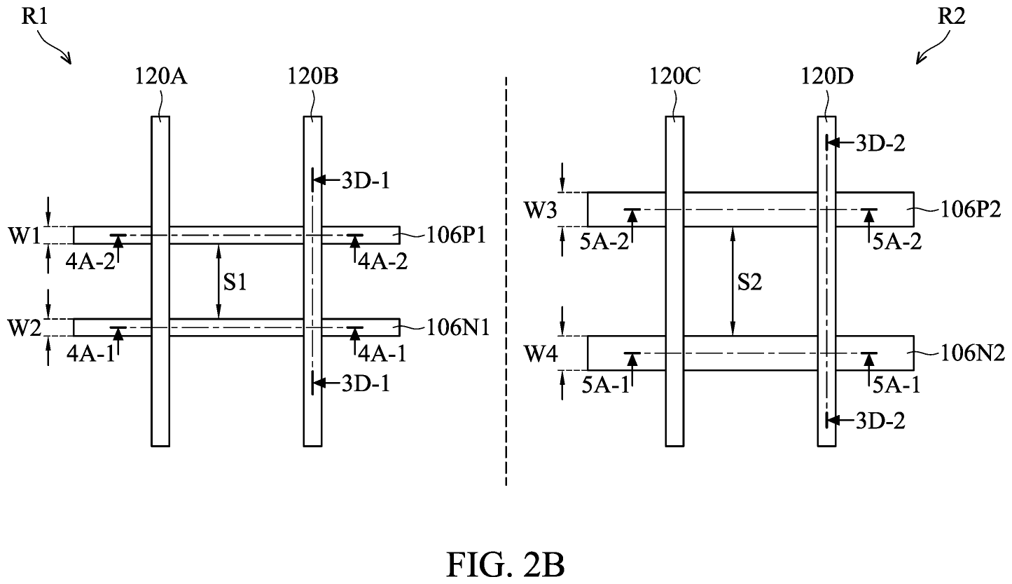

FIGS. 2A-2B are top views of various stages of a process for forming portions of a semiconductor device structure, in accordance with some embodiments. In FIG. 2A, the left side shows a portion of the semiconductor device structure formed in the first region R1, and the right side shows a portion of the semiconductor device structure formed in the second region R2.

As shown in FIG. 2A, multiple fin structures 106N1, 106P1, 106N2, and 106P2 are formed, in accordance with some embodiments. In some embodiments, the fin structures 106N1, 106P1, 106N2, and 106P2 are oriented lengthwise. In some embodiments, the long extension directions of the fin structures 106N1, 106P1, 106N2, and 106P2 are substantially parallel to each other, as shown in FIG. 2A. In some embodiments, FIG. 3B shows the cross-sectional views of the structure taken along the line 3B-1 to 3B-1 and the line 3B-2 to 3B-2 in FIG. 2A.

In some embodiments, the fin structures 106N1 and 106P1 formed in the first region R1 and the fin structures 106N2 and 106P2 formed in the second region R2 have different widths, as shown in FIGS. 2A and 3B. In some embodiments, each of the fin structures 106N2 and 106P2 is wider than each of the fin structures 106N1 and 106P1. As shown in FIGS. 2A and 3B, the fin structures 106N1 and 106P1 are laterally spaced apart from each other by a distance S1, and the fin structures 106N2 and 106P2 are laterally spaced apart from each other by a distance S2. In some embodiments, the distance S2 is longer than the distance S1.

As shown in FIGS. 2A and 3B, the fin structures 106N1 has a width W1, and the fin structure 106P1 has a width W2. Each of the widths W1 and W2 is measured along the long extension direction of a dummy gate stack that will be formed. In some embodiments, the fin structure 106N1 is substantially as wide as the fin structure 106P1. The width W1 is substantially equal to the width W2. The width W1 or W2 may be within a range from about 9 nm to about 20 nm.

As shown in FIGS. 2A and 3B, the fin structures 106N2 has a width W3, and the fin structure 106P2 has a width W4. Each of the widths W3 and W4 is measured along the long extension direction of a dummy gate stack that will be formed. In some embodiments, the fin structure 106N2 is substantially as wide as the fin structure 106P2. The width W3 is substantially equal to the width W4. In some embodiments, the width W3 (or W4) is wider than the width W1 (or W2). The width W3 or W4 may be within a range from about 20 nm to about 60 nm.

Afterwards, as shown in FIG. 3C, an isolation structure 115 is formed to laterally surround lower portions of the fin structures 106N1, 106P1, 106N2, and 106P2, in accordance with some embodiments. In some embodiments, the isolation structure 115 includes dielectric fillings 114 and liner elements 113 that are adjacent to the semiconductor fins 101N1, 101P1, 101N2, and 101P2.

In some embodiments, a liner material layer and one or more dielectric layers for forming the dielectric fillings 114 are deposited over the fin structures 106N1, 106P1, 106N2, and 106P2 and the semiconductor substrate 100. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The liner material layer may be made of or include silicon nitride, silicon oxynitride, silicon carbide, silicon oxycarbide, one or more other suitable materials, or a combination thereof. The dielectric layers and the liner material layer may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers and the liner material layer. The hard mask elements HM1 and HM2 (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers and the liner material layer. As a result, the remaining portions of the dielectric layers form the dielectric fillings 114 of the isolation structure 115. The remaining portions of the liner material layer form the liner elements 113 of the isolation structure 115. Upper portions of the fin structures 106N1, 106P1, 106N2, and 106P2 protrude from the top surface of the isolation structure 115, as shown in FIG. 3C.

In some embodiments, the etching back process for forming the isolation structure 115 is carefully controlled to ensure that the topmost surface of the isolation structure 115 is positioned at a suitable height level, as shown in FIG. 3C. In some embodiments, the topmost surface of the isolation structure 115 is below the bottommost surface of the sacrificial layer 102a.

Afterwards, the hard mask elements HM1 and HM2 (including the first mask layer 108 and the second mask layer 110) are removed. Alternatively, in some other embodiments, the hard mask elements HM1 and HM2 are removed or consumed during the planarization process and/or the etching back process that forms the isolation structure 115.

Afterwards, dummy gate stacks 120A and 120B are formed to extend across the fin structures 106N1 and 106P1, as shown in FIG. 2B in accordance with some embodiments. Dummy gate stacks 120C and 120D are formed to extend across the fin structures 106N2 and 106P2. In some embodiments, FIG. 3D shows the cross-sectional views of the structure taken along the line 3D-1 to 3D-1 and the line 3D-2 to 3D-2 in FIG. 2B.

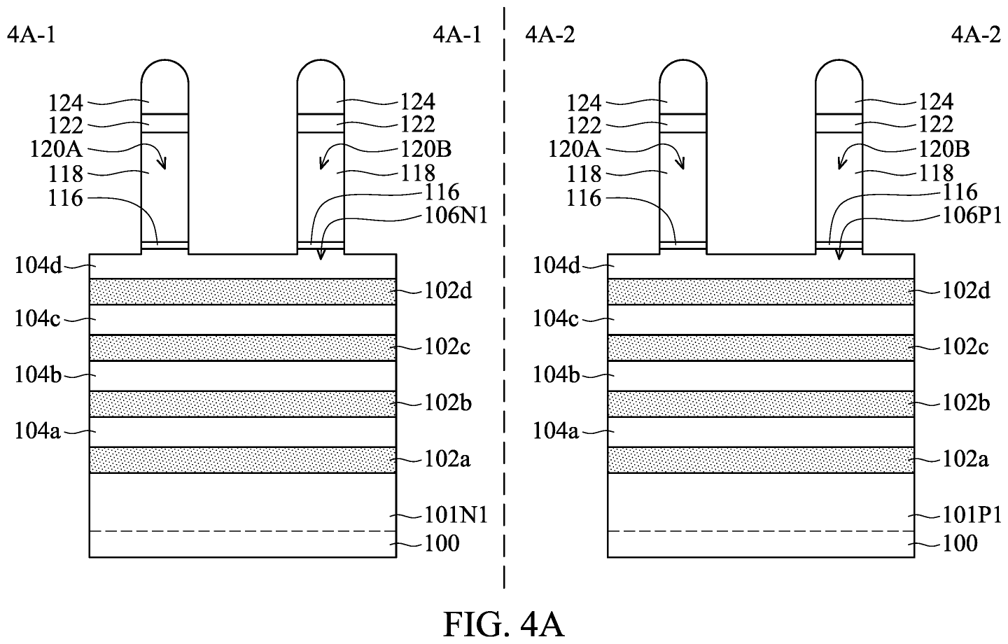

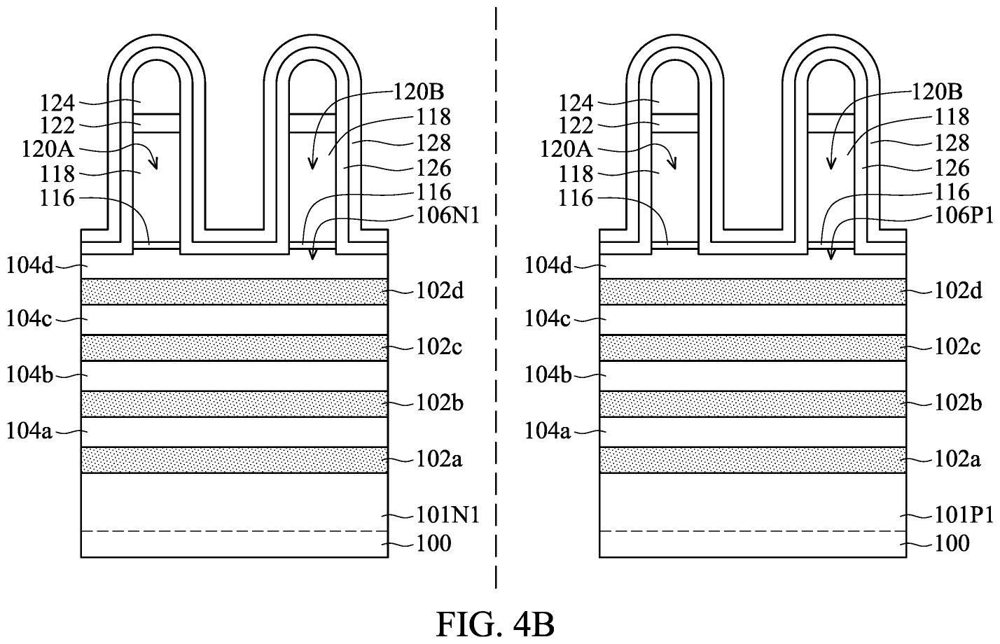

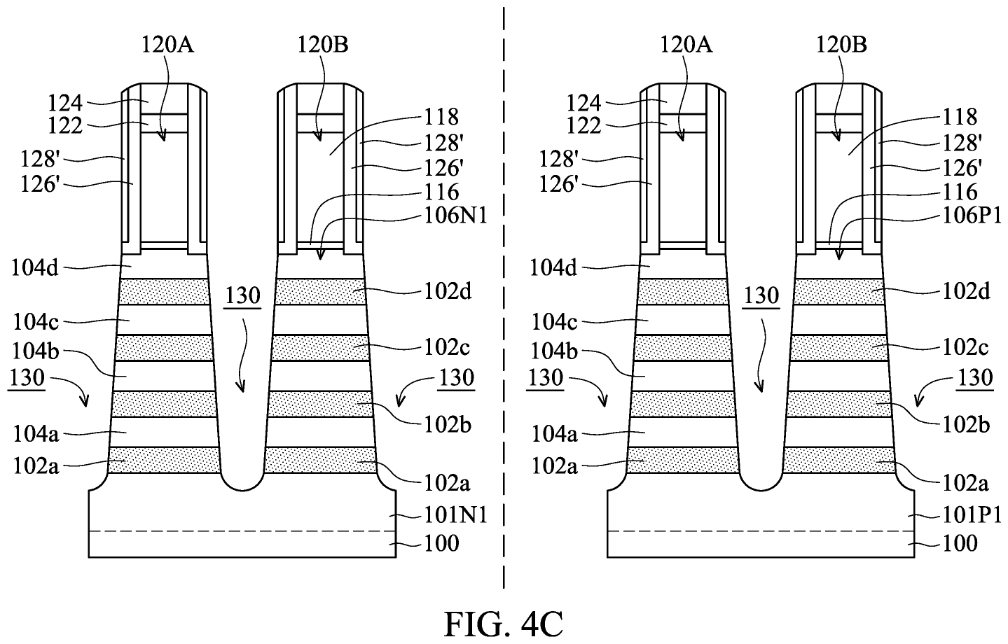

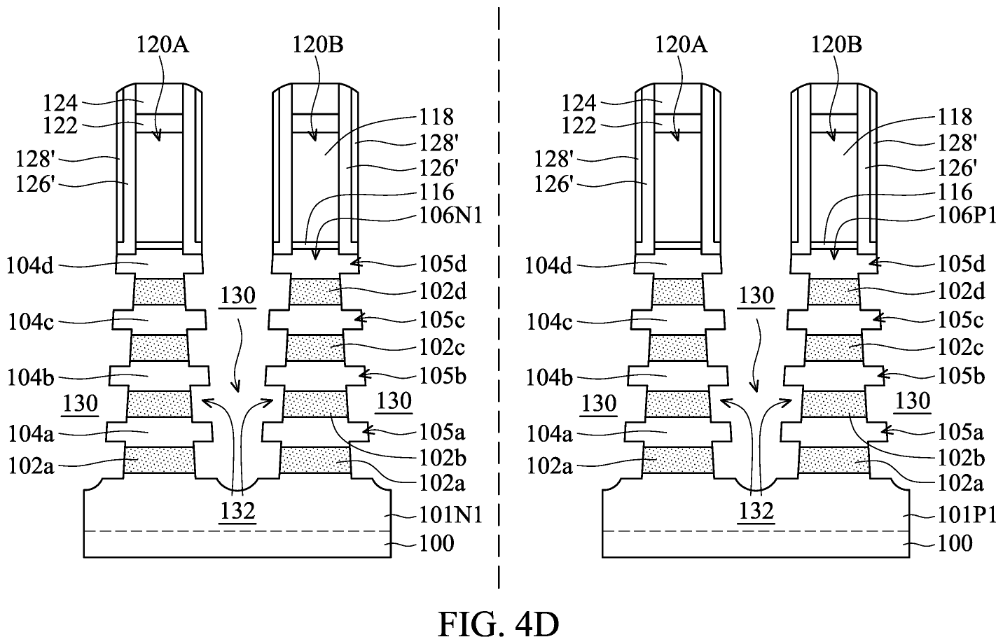

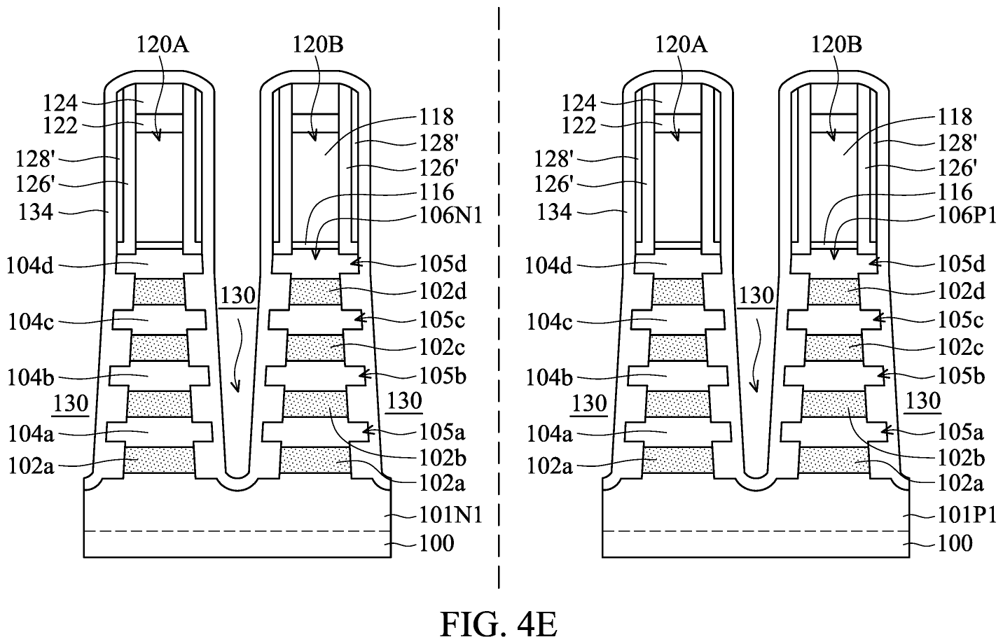

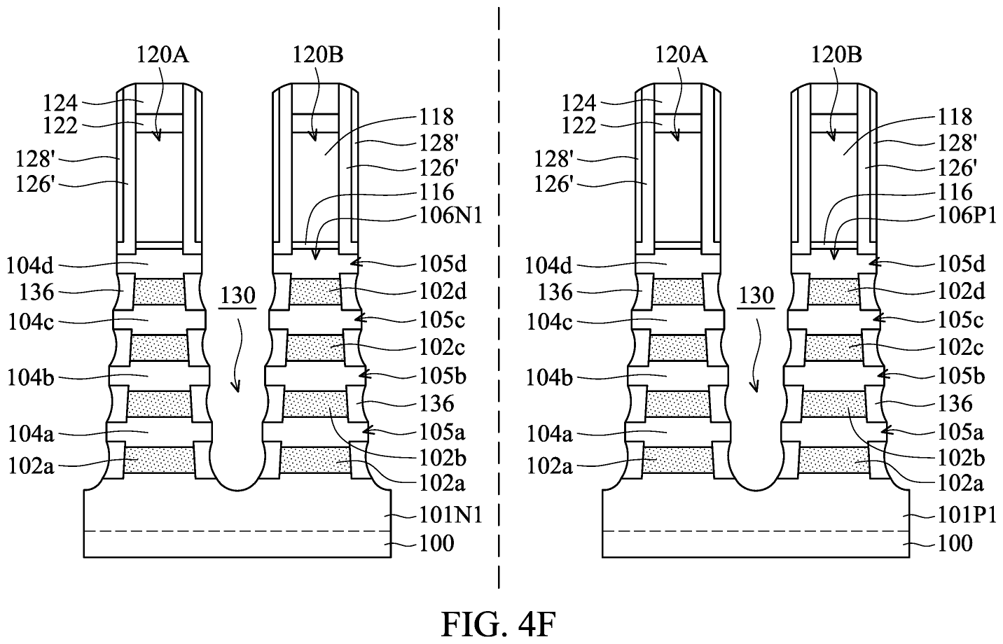

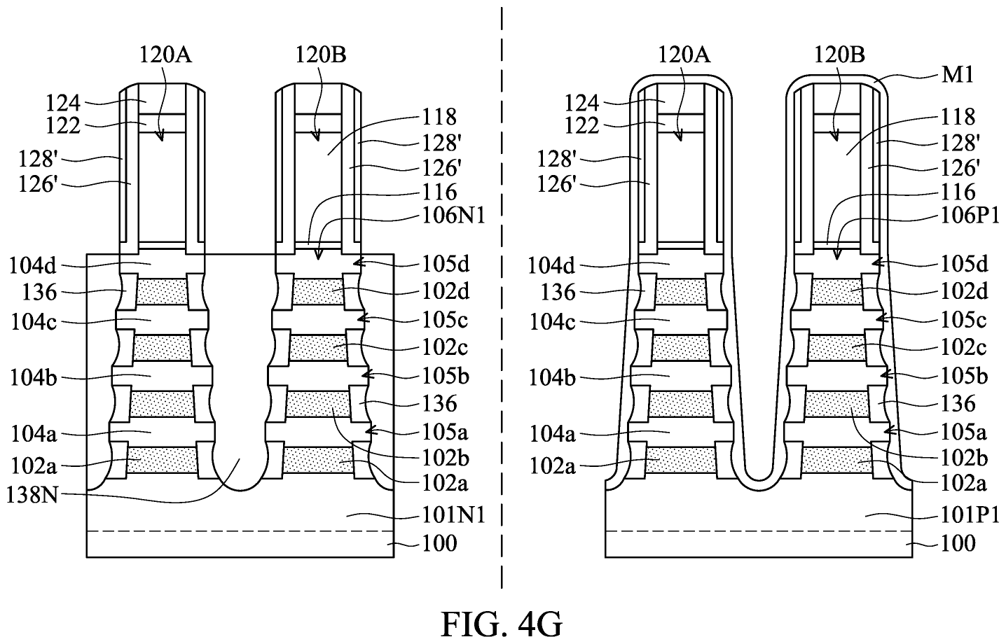

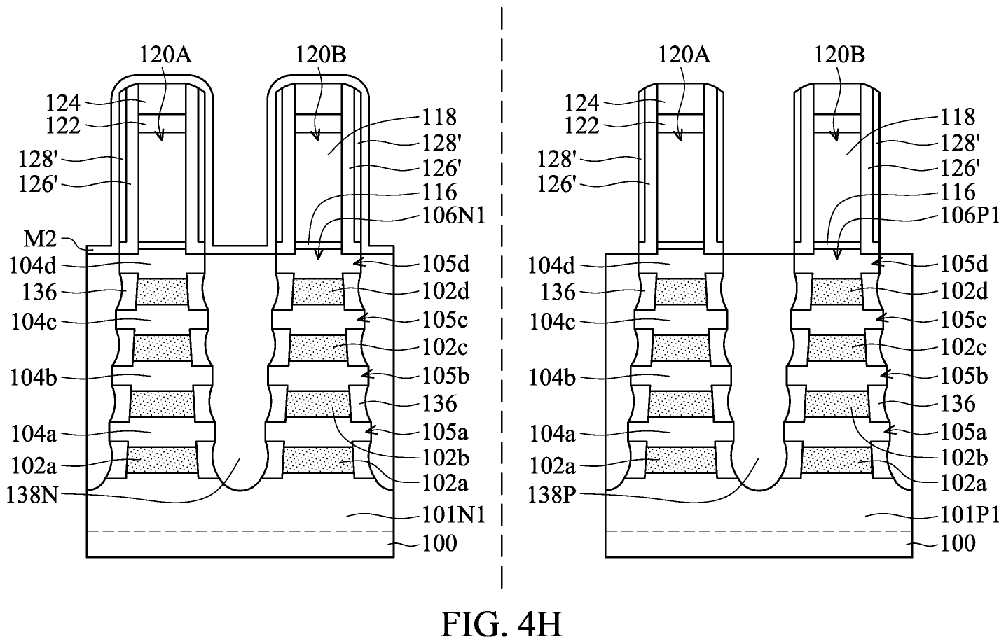

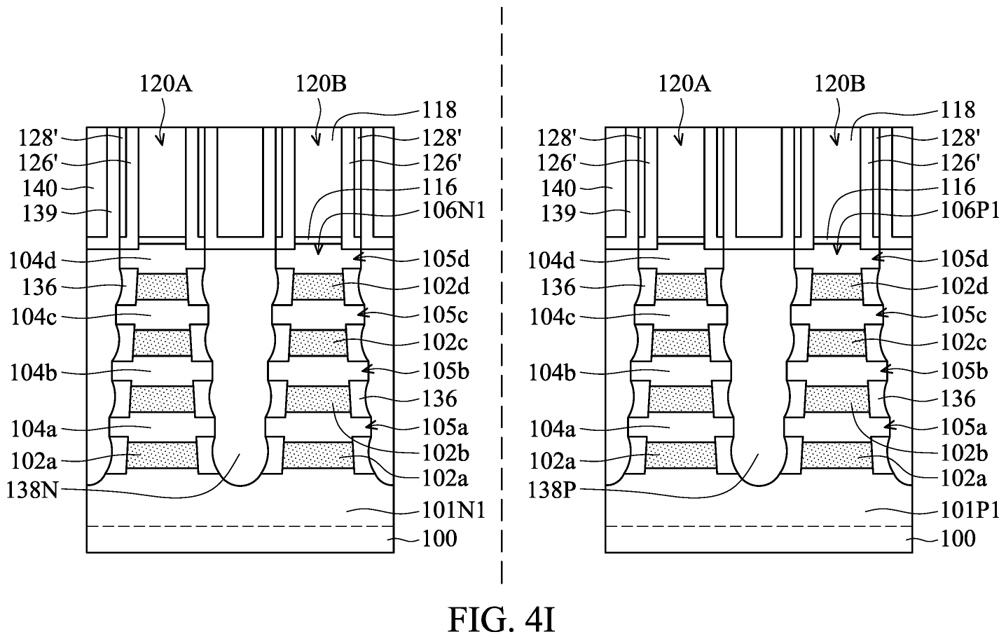

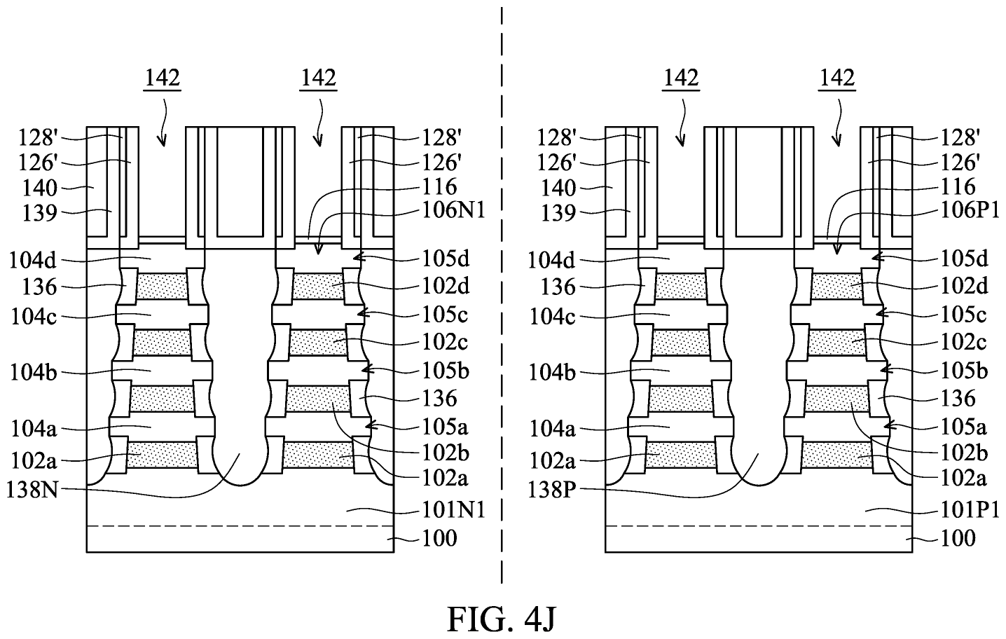

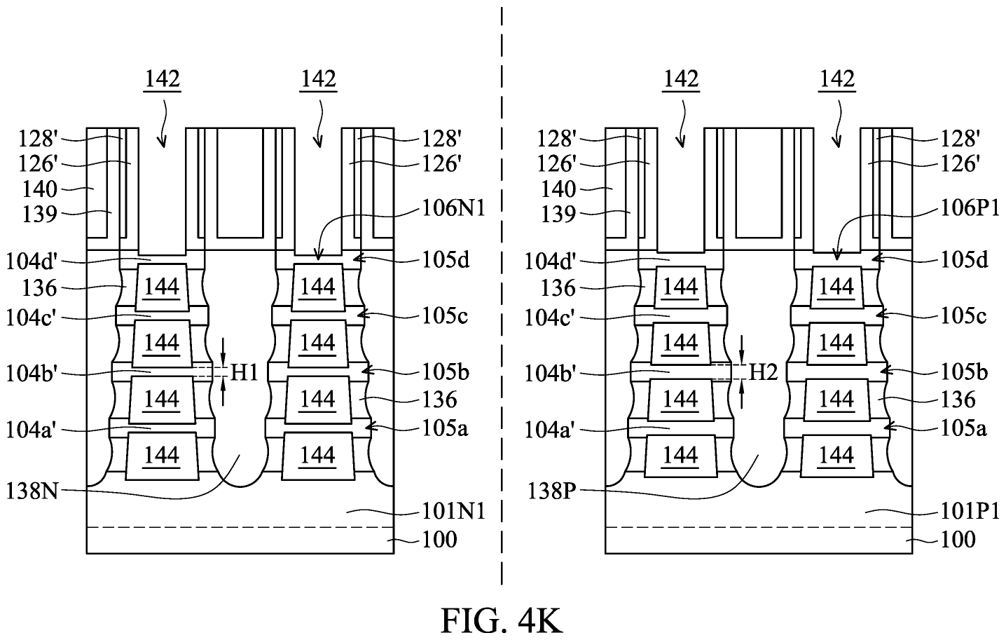

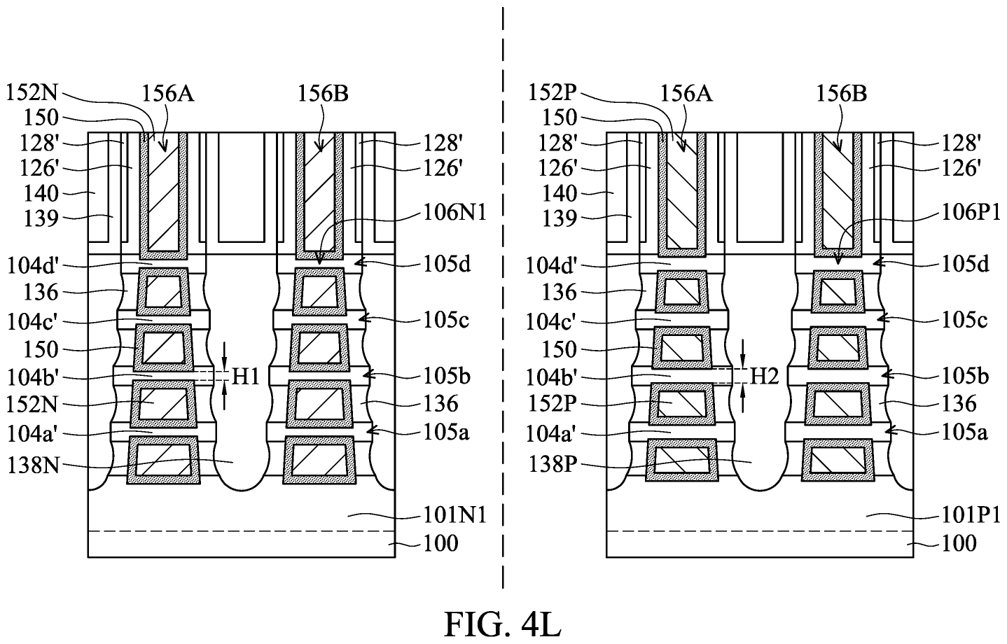

FIGS. 4A-4L are cross-sectional views of various stages of a process for forming portions of a semiconductor device structure, in accordance with some embodiments. In some embodiments, FIG. 4A shows the cross-sectional views of two portions of the structure taken along the line 4A-1 to 4A-1 and the line 4A-2 to 4A-2 in FIG. 2B.

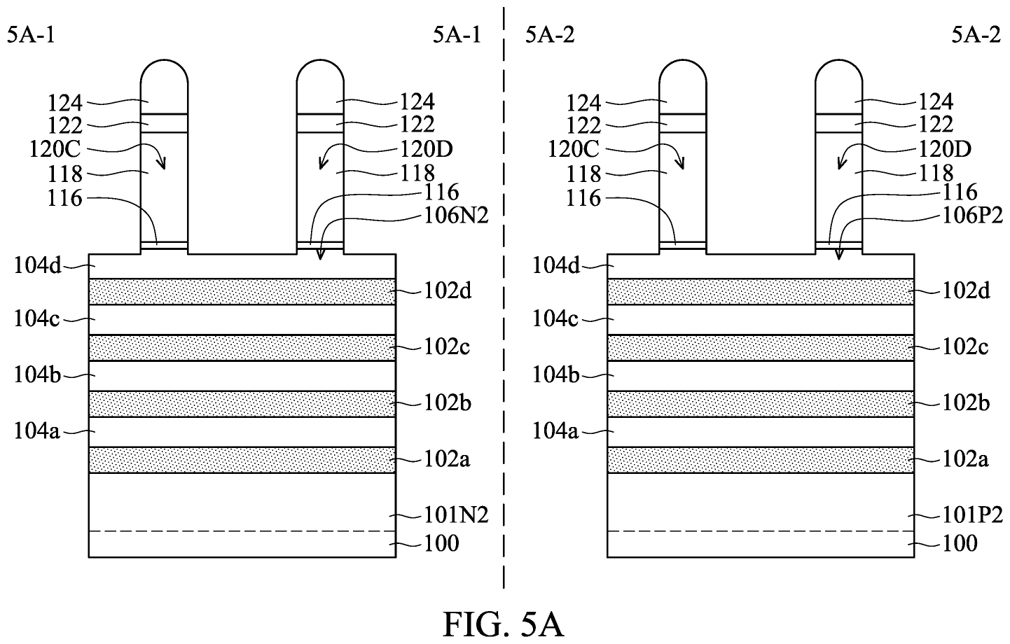

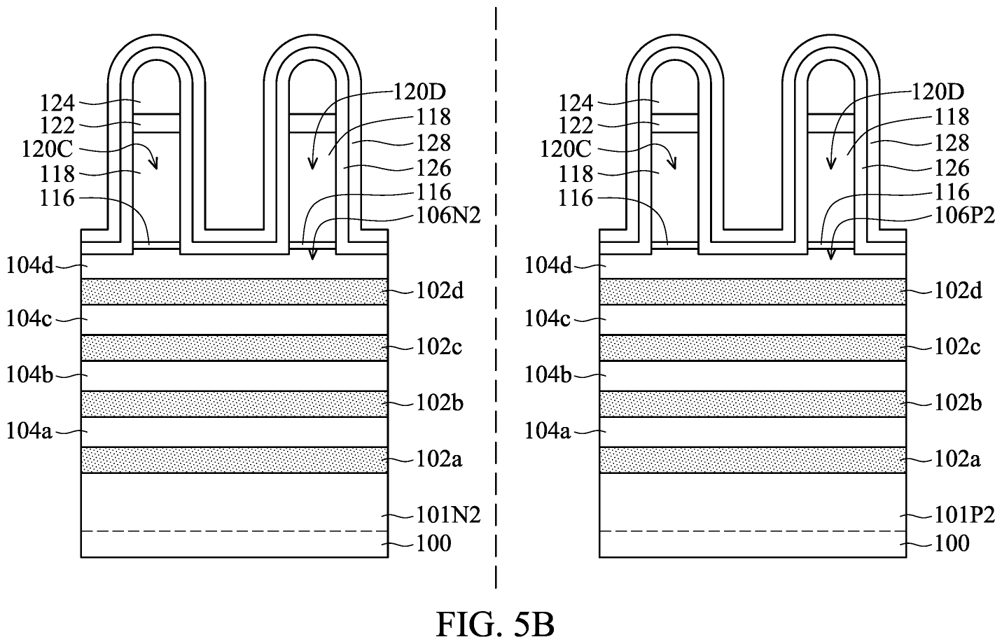

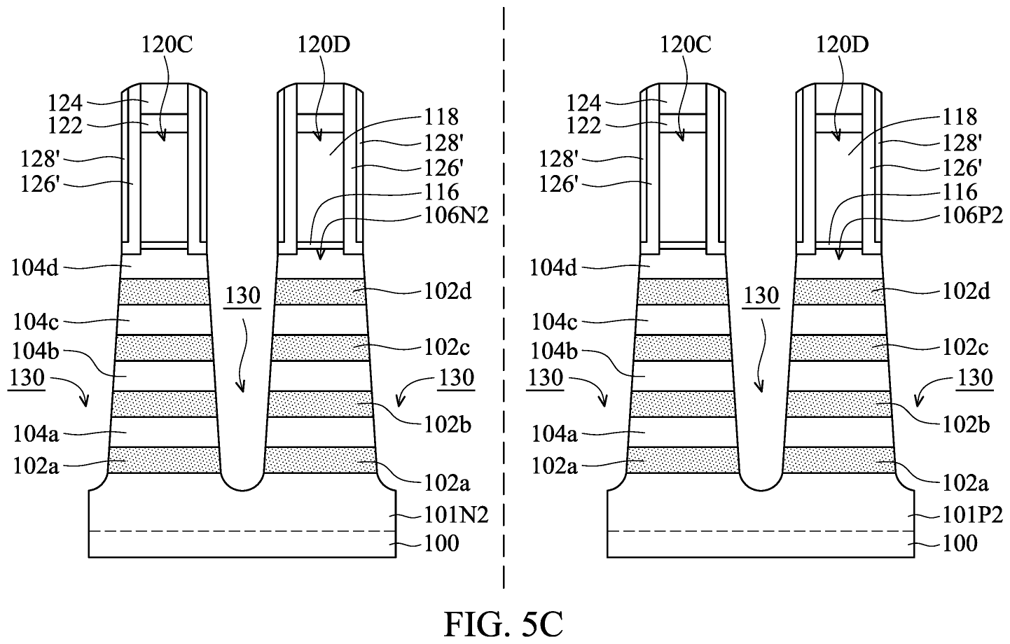

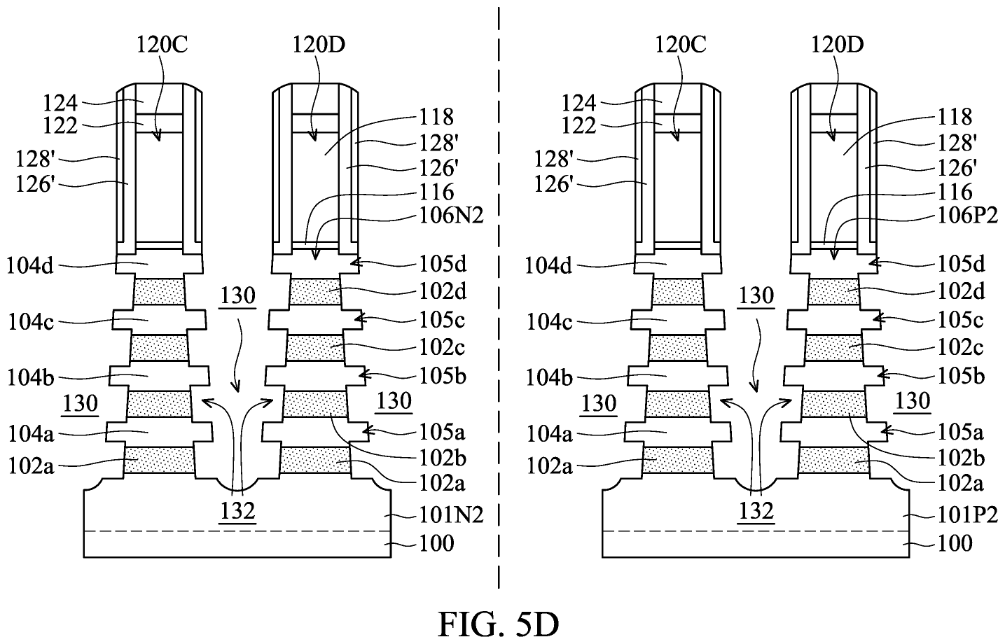

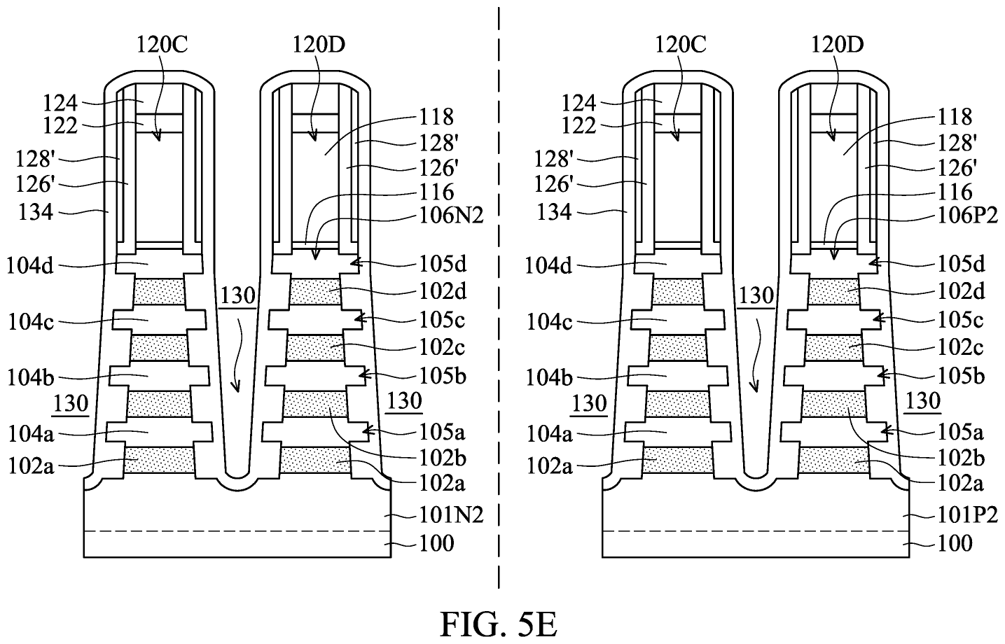

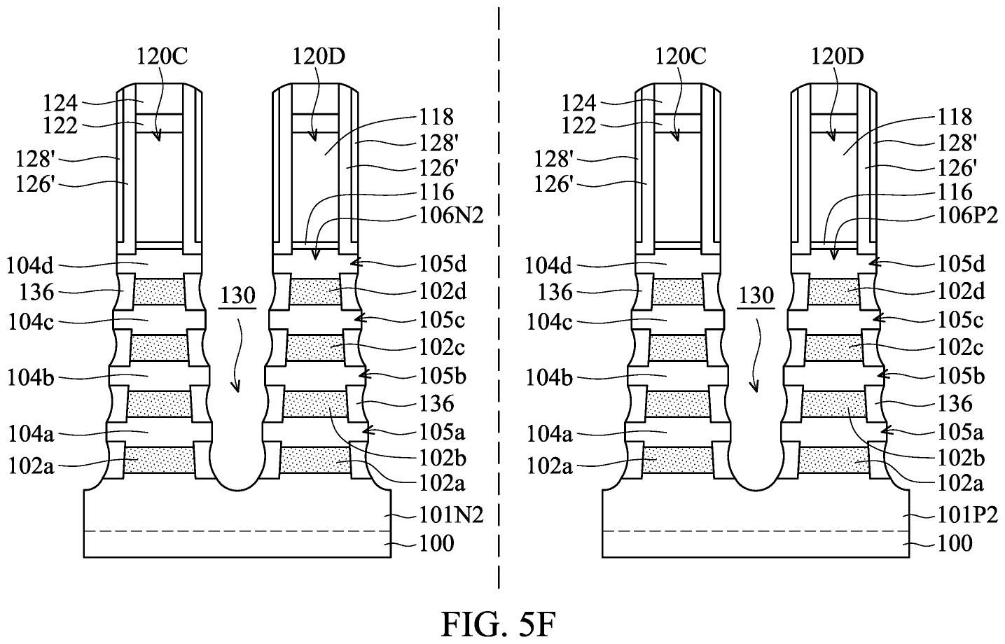

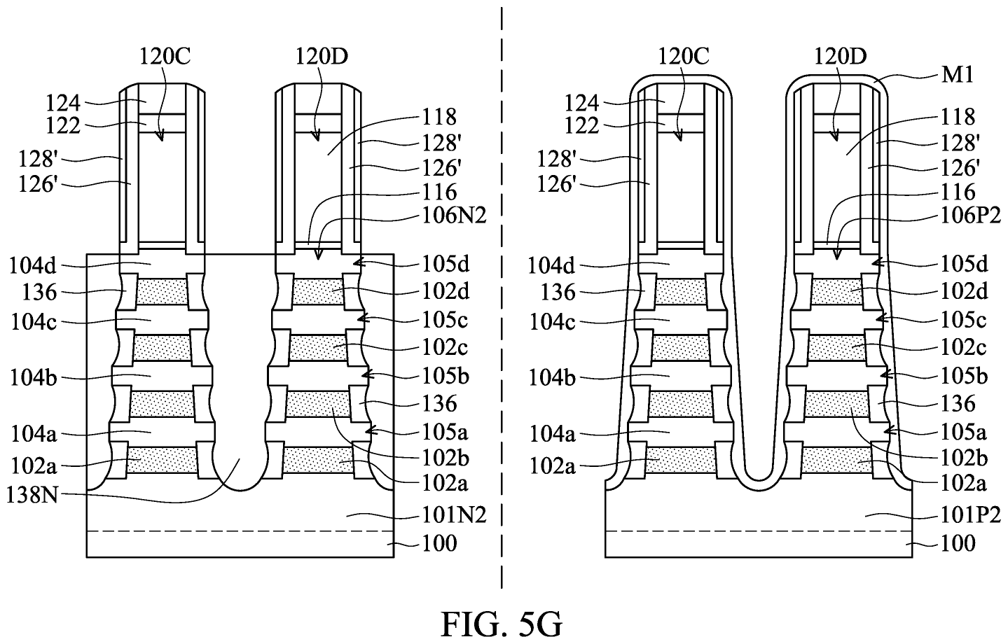

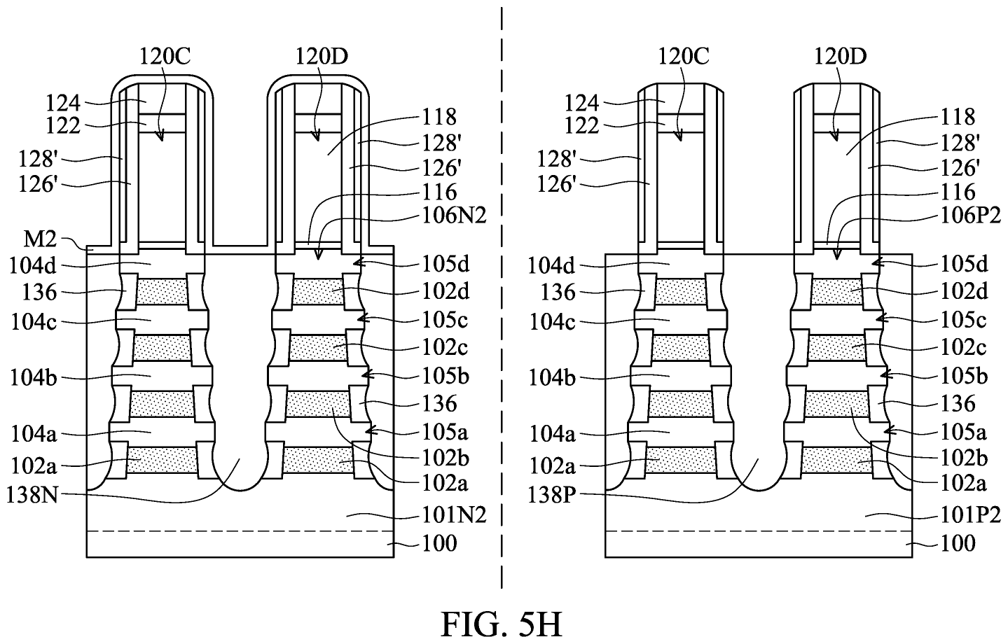

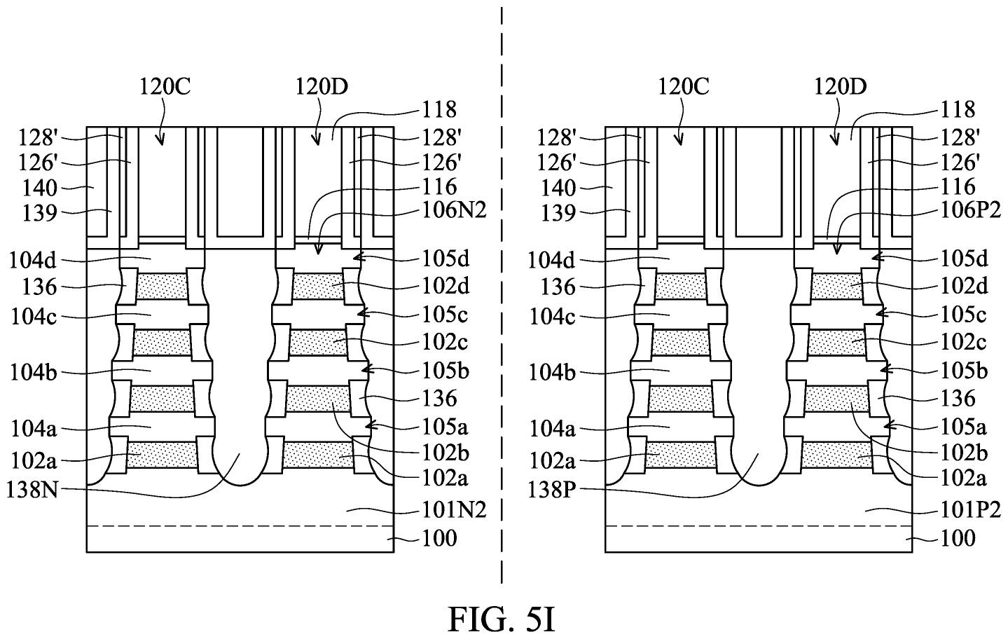

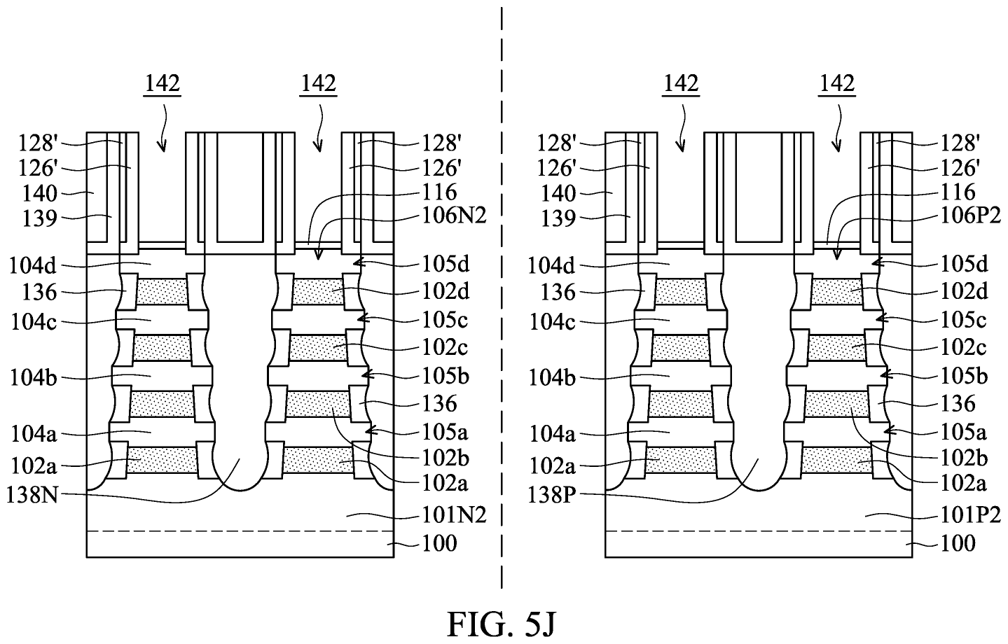

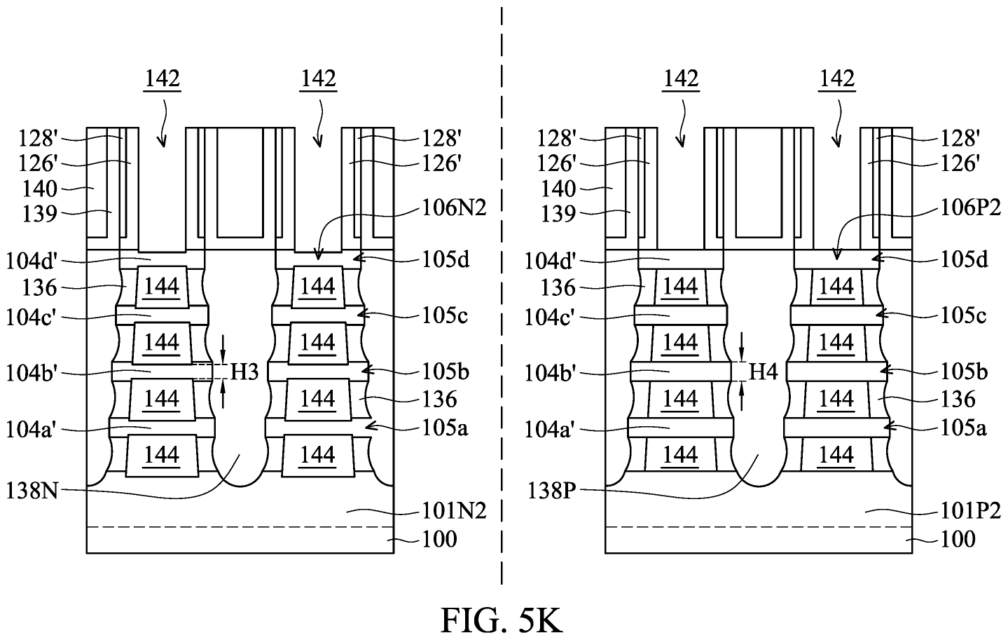

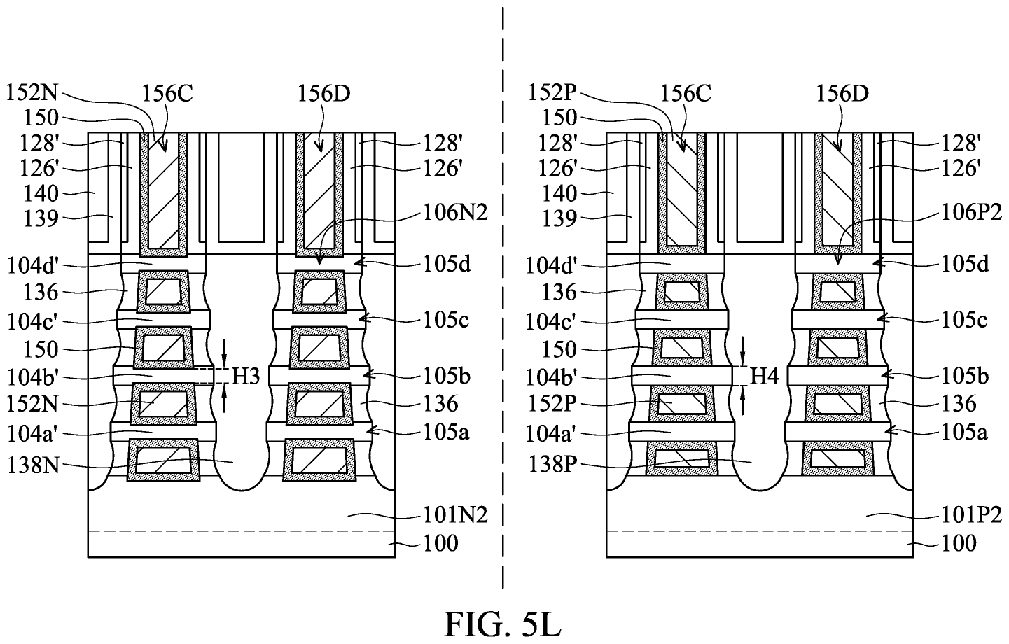

FIGS. 5A-5L are cross-sectional views of various stages of a process for forming portions of a semiconductor device structure, in accordance with some embodiments. In some embodiments, FIG. 5A shows the cross-sectional views of two portions of the structure taken along the line 5A-1 to 5A-1 and the line 5A-2 to 5A-2 in FIG. 2B.

As shown in FIGS. 2B, 3D, and 4A, the dummy gate stacks 120A and 120B partially cover and extend across the fin structures 106N1 and 106P1, in accordance with some embodiments. The dummy gate stacks 120C and 120D partially cover and extend across the fin structures 106N2 and 106P2. In some embodiments, the dummy gate stacks 120A and 120B are wrapped around the fin structures 106N1 and 106P1, and the dummy gate stacks 120C and 120D are wrapped around the fin structures 106N2 and 106P2. As shown in FIG. 3D, the dummy gate stack 120B extends across and is wrapped around the fin structures 106N1 and 106P1, and the dummy gate stack 120D extends across and is wrapped around the fin structures 106N2 and 106P2. As shown in FIG. 2B, other portions of the fin structures 106N1, 106P1, 106N2, and 106P2 are exposed without being covered by the dummy gate stacks 120A-120D.

As shown in FIGS. 3D, 4A, and 5A, each of the dummy gate stacks 120A-120D includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106N1, 106P1, 106N2, and 106P2. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A-120D.

In some embodiments, hard mask elements are used to assist in the patterning process for forming the dummy gate stacks 120A-120D. Each of the hard mask elements may include multiple mask layers 122 and 124. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A-120D.

As shown in FIGS. 4B and 5B, spacer layers 126 and 128 are afterwards deposited over the dummy gate stacks 120A-120D and the fin structures 106N1, 106P1, 106N2, and 106P2, in accordance with some embodiments. The spacer layers 126 and 128 extend along the tops and sidewalls of the dummy gate stacks 120A-120D, as shown in FIGS. 4B and 5B.

In some embodiments, the spacer layers 126 and 128 are made of different materials. The spacer layer 126 may be made of a dielectric material that has a low dielectric constant. The spacer layer 126 may be made of or include silicon carbide, silicon oxycarbide, carbon-containing silicon oxynitride, silicon oxide, one or more other suitable materials, or a combination thereof. In some embodiments, the spacer layer 126 is a single layer. In some other embodiments, the spacer layer 126 includes multiple sub-layers. Some of the sub-layers may be made of different materials. Some of the sub-layers may be made of similar materials with different compositions. For example, one of the sub-layers may have a greater atomic concentration of carbon than other sub-layers.

The spacer layer 128 may be made of a dielectric material that can provide more protection to the gate stacks during subsequent processes. The spacer layer 128 may have a greater dielectric constant than that of the spacer layer 126. The spacer layer 128 may be made of silicon nitride, silicon oxynitride, carbon-containing silicon nitride, carbon-containing silicon oxynitride, one or more other suitable materials, or a combination thereof. The spacer layers 126 and 128 may be sequentially deposited using a CVD process, an ALD process, a physical vapor deposition (PVD) process, one or more other applicable processes, or a combination thereof.

However, embodiments of the disclosure are not limited thereto. Many variations and/or modifications can be made to embodiments of the disclosure. In some other embodiments, the spacer layers 126 and 128 are made of the same material. In some other embodiments, the spacer layer 128 is formed before the spacer layer 126. In these cases, the spacer layer 128 is between the spacer layer 126 and the dummy gate electrode 118.

As shown in FIGS. 4C and 5C, the spacer layers 126 and 128 are partially removed, in accordance with some embodiments. One or more anisotropic etching processes may be used to partially remove the spacer layers 126 and 128. As a result, remaining portions of the spacer layers 126 and 128 form gate spacers 126′ and 128′, respectively. The gate spacers 126′ and 128′ extend along the sidewalls of the dummy gate stacks 120A-120D, as shown in FIGS. 4C and 5C.

As shown in FIGS. 4C and 5C, the fin structure 106N1, 106P1, 106N2, and 106P2 are partially removed, in accordance with some embodiments. As a result, the recesses 130 are formed, as shown in FIGS. 4C and 5C. The recesses 130 may be used to contain epitaxial structures (such as source/drain structures) that will be formed later. In this disclosure, source/drain structure(s) (or region(s)) may refer to a source or a drain, individually or collectively dependent upon the context.

One or more etching processes may be used to form the recesses 130. In some embodiments, a dry etching process is used to form the recesses 130. Alternatively, a wet etching process may be used to form the recesses 130. In some embodiments, the recesses 130 penetrate into the fin structures 106N1, 106P1, 106N2, and 106P2. In some embodiments, the recesses 130 further extend into the semiconductor fins 101N1, 101P1, 101N2, and 101P2, as shown in FIGS. 4C and 5C. In some embodiments, the gate spacers 126′ and 128′ and the recesses 130 are formed simultaneously using the same etching process.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104d) is shorter than a lower semiconductor layer (such as the semiconductor layer 104b).

However, embodiments of the disclosure have many variations. In some other embodiments, the recesses 130 have substantially vertical sidewalls. By fine-tuning the etching conditions, the profile of the recesses 130 may be modified. In these cases, due to the profile of the recesses 130, an upper semiconductor layer (such as the semiconductor layer 104d) is substantially as wide as a lower semiconductor layer (such as the semiconductor layer 104b).

Afterwards, as shown in FIGS. 4D and 5D, the sacrificial layers 102a-102d are laterally etched, in accordance with some embodiments. As a result, edges of the sacrificial layers 102a-102d retreat from edges of the semiconductor layers 104a-104d. As shown in FIGS. 4D and 5D, recesses 132 are formed due to the lateral etching of the sacrificial layers 102a-102d. The recesses 132 may be used to contain inner spacers that will be formed later. The sacrificial layers 102a-102d may be laterally etched using a wet etching process, a dry etching process, or a combination thereof. In some other embodiments, the sacrificial layers 102a-102d are partially oxidized before being laterally etched.

During the lateral etching of the sacrificial layers 102a-102d, the semiconductor layers 104a-104d may also be slightly etched. As a result, edge portions of the semiconductor layers 104a-104d are partially etched and thus shrink to become edge elements 105a-105d, as shown in FIGS. 4D and 5D. As shown in FIGS. 4D and 5D, each of the edge elements 105a-105d of the semiconductor layers 104a-104d is thinner than the respective inner portion of the semiconductor layers 104a-104d.

As shown in FIGS. 4E and 5E, an insulating layer 134 is deposited over the structure shown in FIGS. 4D and 5D, in accordance with some embodiments. The insulating layer 134 covers the dummy gate stacks 120A-120D and fills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, one or more other suitable materials, or a combination thereof. In some embodiments, the insulating layer 134 is a single layer. In some other embodiments, the insulating layer 134 includes multiple sub-layers. Some of the sub-layers may be made of different materials and/or contain different compositions. The insulating layer 134 may be deposited using a CVD process, an ALD process, another applicable process, or a combination thereof.

As shown in FIGS. 4F and 5F, an etching process is used to partially remove the insulating layer 134, in accordance with some embodiments. The portions of the insulating layer 134 outside of the recesses 132 may be removed. The remaining portions of the insulating layer 134 form inner spacers 136, as shown in FIGS. 4F and 5F. The etching process may include a dry etching process, a wet etching process, or a combination thereof.

The inner spacers 136 cover the edges of the sacrificial layers 102a-102d. The inner spacers 136 may be used to prevent subsequently formed epitaxial structures (that function as, for example, source/drain structures) from being damaged during a subsequent process for removing the sacrificial layers 102a-102d. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fins 101N1, 101P1, 101P2 and 101N2 originally covered by the insulating layer 134 are exposed by the recesses 130, as shown in FIGS. 4F and 5F. The edges of the semiconductor layers 104a-104d are exposed by the recesses 130, as shown in FIGS. 4F and 5F.

As shown in FIGS. 4G and 5G, a mask element M1 is formed to cover the semiconductor fins 101P1 and 101P2 and the fin structures 106P1 and 106P2, in accordance with some embodiments. One or more photolithography processes and one or more etching processes may be used to form the mask element M1 with the desired pattern.

Afterwards, epitaxial structures 138N are formed on the semiconductor fins 101N1 and 101N2 and the side surfaces of the semiconductor layers 104a-104d of the fin structures 106N1 and 106N2 that are not covered by the mask element M1, as shown in FIGS. 4G and 5G in accordance with some embodiments. In some embodiments, the epitaxial structures 138N fill the recesses 130 that are not covered by the mask element M1, as shown in FIGS. 4G and 5G. In some other embodiments, the epitaxial structures 138N overfill the recesses 130 to ensure fully contact between the epitaxial structures 138N and the semiconductor layers 104d nearby. In some embodiments, the top surfaces of the epitaxial structures 138N are higher than the top surface of the dummy gate dielectric layer 116. In some other embodiments, the epitaxial structures 138N partially fill the recesses 130.

In some embodiments, the epitaxial structures 138N connect to some of the semiconductor layers 104a-104d. Some of the semiconductor layers 104a-104d are sandwiched between the epitaxial structures 138N. In some embodiments, the epitaxial structures 138N are n-type doped epitaxial structures. The epitaxial structures 138N may include epitaxially grown silicon or another suitable epitaxially grown semiconductor material.

In some embodiments, the epitaxial structures 138N are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof. In some embodiments, the formation of the epitaxial structures 138N involves one or more etching processes that are used to fine-tune the shapes of the epitaxial structures 138N.

In some embodiments, the epitaxial structures 138N are doped with one or more suitable n-type dopants. For example, the epitaxial structures 138N are Si source/drain features that are doped with phosphor (P), antimony (Sb), arsenic (As) or another suitable dopant. In some embodiments, each of the epitaxial structures 138N has a first region and a second region over the first region. The second region may have a greater dopant concentration than that of the first region.

In some embodiments, the epitaxial structures 138N are doped in-situ during their epitaxial growth. The initial reaction gas mixture for forming the epitaxial structures 138N contains dopants. In some other embodiments, the epitaxial structures 138N are not doped during the growth of the epitaxial structures 138N. Instead, after the formation of the epitaxial structures 138N, the epitaxial structures 138N are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138N are further exposed to one or more annealing processes to activate the dopants. For example, a rapid thermal annealing process is used. Some n-type dopants may diffuse into the semiconductor layers 104a-104d and the sacrificial layers 102a-102d that are nearby from the epitaxial structures 138N.

As shown in FIGS. 4H and 5H, the mask element M1 is removed, and a mask element M2 is formed to cover the epitaxial structures 138N, in accordance with some embodiments. Afterwards, epitaxial structures 138P are formed on the semiconductor fins 101P1 and 101P2 and the semiconductor layers 104a-104d of the fin structures 106P1 and 106P2 that are exposed without being covered by the mask element M2, in accordance with some embodiments. In some embodiments, the epitaxial structures 138P fill the recesses 130 that are not covered by the mask element M2, as shown in FIGS. 4H and 5H. In some other embodiments, the epitaxial structures 138P overfill the recesses 130 to ensure fully contact between the epitaxial structures 138P and the semiconductor layers 104d nearby. In some embodiments, the top surfaces of the epitaxial structures 138P are higher than the top surface of the dummy gate dielectric layer 116. In some other embodiments, the epitaxial structures 138P partially fill the recesses 130.

In some embodiments, the epitaxial structures 138P connect to some of the semiconductor layers 104a-104d. Some of the semiconductor layers 104a-104d are sandwiched between the epitaxial structures 138P. In some embodiments, the epitaxial structures 138P are p-type doped epitaxial structures. The epitaxial structures 138P may include epitaxially grown silicon germanium, epitaxially grown silicon, or another suitable epitaxially grown semiconductor material.

In some embodiments, the epitaxial structures 138P are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138P involves one or more etching processes that are used to fine-tune the shapes of the epitaxial structures 138P.

In some embodiments, the epitaxial structures 138P are doped with one or more suitable p-type dopants. For example, the epitaxial structures 138P are SiGe source/drain features or Si source/drain features that are doped with boron (B), gallium (Ga), indium (In), or another suitable dopant. In some embodiments, each of the epitaxial structures 138P has a first region and a second region over the first region. The second region may have a greater dopant concentration than that of the first region.

In some embodiments, the epitaxial structures 138P are doped in-situ during their epitaxial growth. The initial reaction gas mixture for forming the epitaxial structures 138P contains dopants. In some other embodiments, the epitaxial structures 138P are not doped during the growth of the epitaxial structures 138P. Instead, after the formation of the epitaxial structures 138P, the epitaxial structures 138P are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138P are further exposed to one or more annealing processes to activate the dopants. For example, a rapid thermal annealing process is used.

In some embodiments illustrated in FIGS. 4G-4H and 5G-5H, the epitaxial structures 138N are formed before the epitaxial structures 138P. However, embodiments of the disclosure are not limited thereto. Many variations and/or modifications can be made to embodiments of the disclosure. In some other embodiments, the epitaxial structures 138P are formed before the epitaxial structures 138N.

As shown in FIGS. 4I and 5I, the mask element M2 is removed, and a contact etch stop layer 139 and a dielectric layer 140 are formed over the epitaxial structures 138N and 138P to laterally surround the dummy gate stacks 120A-120D, in accordance with some embodiments. The contact etch stop layer 139 may be made of or include silicon nitride, silicon oxynitride, silicon carbide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited. The etch stop material layer may be deposited using a CVD process, an ALD process, a PVD process, another applicable process, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIGS. 4I and 5I. The planarization process may include a CMP process, a grinding process, an etching process, a dry polishing process, another applicable process, or a combination thereof. In some embodiments, the mask elements used for defining the dummy gate stacks 120A-120D are removed during the planarization process. In some embodiments, after the planarization process, the top surfaces of the contact etch stop layer 139, the dielectric layer 140, and the dummy gate electrodes 118 are substantially level.

Afterwards, as shown in FIGS. 3E, 4J, and 5J, the dummy gate electrodes 118 are removed to form trenches 142 using one or more etching processes, in accordance with some embodiments. The trenches 142 are surrounded by the dielectric layer 140. The trenches 142 expose the dummy gate dielectric layer 116.

As shown in FIGS. 3F, 4K, and 5K, the dummy gate dielectric layer 116 and the sacrificial layers 102a-102d are removed, in accordance with some embodiments. In some embodiments, one or more etching processes are used to remove the dummy gate dielectric layer 116 and the sacrificial layers 102a-102d. As a result, recesses 144 are formed, as shown in FIGS. 3F, 4K, and 5K.

Due to high etching selectivity, the semiconductor layers 104a-104d are slightly (or substantially not) etched. The remaining portions of the semiconductor layers 104a-104d form multiple semiconductor nanostructures 104a′-104d′. The semiconductor nanostructures 104a′-104d′ are constructed by or made up of the remaining portions of the semiconductor layers 104a-104d. The semiconductor nanostructures 104a′-104d′ suspended over the semiconductor fins 101N1, 101P1, 101N2, and 101P2 may function as channel structures of transistors. The semiconductor nanostructures 104a′-104d′ may be nanosheets or may have another suitable profile.

In some embodiments, the etchant used for removing the sacrificial layers 102a-102d also slightly removes the semiconductor layers 104a-104d that form the semiconductor nanostructures 104a′-104d′. As a result, the obtained semiconductor nanostructures 104a′-104d′ become thinner after the removal of the sacrificial layers 102a-102d. In some embodiments, some of the semiconductor nanostructures 104a′-104d′ (such as those over the semiconductor fins 101N1, 101P1, and 101N2) are thinner than the edge portions 105a-105d since the edge portions 105a-105d are surrounded by other elements and are thus prevented from being reached and etched by the etchant.

In some embodiments, the semiconductor nanostructures 104a′-104d′ over the semiconductor fins 101N1, 101P1, 101N2, and 101P2 are formed simultaneously. One or more etching processes may be used to remove the sacrificial layers 102a-102d and to form the semiconductor nanostructures 104a′-104d′. In some embodiments, some n-type dopants may diffuse into the semiconductor layers 104a-104d and the sacrificial layers 102a-102d that are adjacent to the epitaxial structures 138N. Due to the n-type dopants, the semiconductor layers 104a-104d and the sacrificial layers 102a-102d near the epitaxial structures 138N may be etched at a higher etching rate during the formation of the semiconductor nanostructures 104a′-104d′.

In some embodiments, the semiconductor layers 104a-104d of a narrower fin structure (such as the fin structure 106N1 or 106P1) may be etched at a higher etching rate than a wider fin structure (such as the fin structure 106N2 or 106P2) during the formation of the semiconductor nanostructures 104a′-104d′.

As shown in FIGS. 3F, 4K, and 5K, each of the semiconductor nanostructures 104a′-104d′ over the semiconductor fin 101N1 has a thickness H1, each of the semiconductor nanostructures 104a′-104d′ over the semiconductor fin 101P1 has a thickness H2, each of the semiconductor nanostructures 104a′-104d′ over the semiconductor fin 101N2 has a thickness H3, and each of the semiconductor nanostructures 104a′-104d′ over the semiconductor fin 101P2 has a thickness H4. In some embodiments, the thickness H2 is higher than the thickness H1. In some embodiments, the thickness H4 is thicker than the thickness H3, and the thickness H3 is thicker than the thickness H1.

The thickness H1 may be within a range from about 0.3 nm to about 0.7 nm. The thickness H2 may be within a range from about 0.5 nm to about 1.2 nm. The thickness H3 may be within a range from about 0.5 nm to about 1.2 nm. The thickness H2 may be within a range from about 0.7 nm to about 1.7 nm.

After the removal of the sacrificial layers 102a-102d, the recesses 144 are formed. The recesses 144 connect to the trench 142 and surround each of the semiconductor nanostructures 104a′-104d′. As shown in FIGS. 3F, 4K, and 5K, even if the recesses 144 between the semiconductor nanostructures 104a′-104d′ are formed, the semiconductor nanostructures 104a′-104d′ remain held by the epitaxial structures 138N or 138P. Therefore, after the removal of the sacrificial layers 102a-102d, the released semiconductor nanostructures 104a′-104d′ are prevented from falling.

During the removal of the sacrificial layers 102a-102d, the inner spacers 136 may protect the epitaxial structures 138N and 138P from being etched or damaged. The quality and reliability of the semiconductor device structure are improved.

As shown in FIGS. 3G, 4L, and 5L, metal gate stacks 156A, 156B, 156C, and 156D are formed to fill the trenches 142, in accordance with some embodiments. The metal gate stacks 156A-156D further extend into the recesses 144 to wrap around each of the semiconductor nanostructures 104a′-104d′.

Each of the metal gate stacks 156A-156D includes multiple metal gate stack layers. Each of the metal gate stacks 156A-156D may include a gate dielectric layer 150 and metal gate electrodes 152P and 152N. Each of the metal gate electrodes 152P and 152N may include a work function layer. Each of the metal gate electrodes 152P and 152N may further include a conductive filling. In some embodiments, the formation of the metal gate stacks 156A-156D involves the deposition of multiple metal gate stack layers over the dielectric layer 140 to fill the trenches 142 and the recesses 144. The metal gate stack layers extend into the recesses 144 to wrap around each of the semiconductor nanostructures 104a′-104d′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, one or more other applicable processes, or a combination thereof.

In some embodiments, before the formation of the gate dielectric layer 150, an interfacial layers are formed on the surfaces of the semiconductor nanostructures 104a′-104d′. The interfacial layers are very thin and are made of, for example, silicon oxide or germanium oxide. In some embodiments, the interfacial layers are formed by applying an oxidizing agent on the surfaces of the semiconductor nanostructures 104a′-104d′. For example, a hydrogen peroxide-containing liquid may be applied or provided on the surfaces of the semiconductor nanostructures 104a′-104d′ so as to form the interfacial layers.

The work function layer of the metal gate electrodes 152P and 152N may be used to provide the desired work function for transistors to enhance device performance including improved threshold voltage. The metal gate electrodes 152P and 152N may have different work function layers.

In some embodiments, the work function layer surrounding the semiconductor nanostructures 104a′-104d′ of the fin structures 106P1 and 106P2 is used for forming PMOS devices. In these cases, the work function layer of the metal gate electrode 152P is a p-type work function layer. The p-type work function layer is capable of providing a work function value suitable for the device, such as equal to or greater than about 4.8 eV.

The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof.

In some embodiments, the work function layer surrounding the semiconductor nanostructures 104a′-104d′ of the fin structures 106N1 and 106N2 is used for forming an NMOS devices. The work function layer of the metal gate electrode 152N is an n-type work function layer. The n-type work function layer is capable of providing a work function value suitable for the device, such as equal to or less than about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAlC, TiAlO, TiAlN, one or more other suitable materials, or a combination thereof.

The work function layer of the metal gate electrodes 152N and 152P may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electrochemical plating process, one or more other applicable processes, or a combination thereof. In some embodiments, the formation of the work function layer involves one or more patterning processes. As a result, the n-type work function layer and the p-type work function layer are selectively formed over different regions.

In some embodiments, a barrier layer is formed before the work function layer to interface the gate dielectric layer 150 with the subsequently formed work function layer. The barrier layer may also be used to prevent diffusion between the gate dielectric layer 150 and the subsequently formed work function layer.

The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electrochemical plating process, one or more other applicable processes, or a combination thereof.

In some embodiments, the conductive fillings of the metal gate electrodes 152N and 152P are made of or include a metal material. The metal material may include tungsten, aluminum, copper, cobalt, one or more other suitable materials, or a combination thereof. A conductive layer used for forming the conductive filling may be deposited over the work function layer using a CVD process, an ALD process, a PVD process, an electroplating process, an electrochemical plating process, a spin coating process, one or more other applicable processes, or a combination thereof.

In some embodiments, a blocking layer is formed over the work function layer before the formation of the conductive layer used for forming the conductive filling. The blocking layer may be used to prevent the subsequently formed conductive layer from diffusing or penetrating into the work function layer.

The blocking layer may be made of or include tantalum nitride, titanium nitride, one or more other suitable materials, or a combination thereof. The blocking layer may be deposited using an ALD process, a PVD process, an electroplating process, an electrochemical plating process, one or more other applicable processes, or a combination thereof.

Afterwards, a planarization process is performed to remove the portions of the metal gate stack layers outside of the trenches 142, in accordance with some embodiments. As a result, the remaining portions of the metal gate stack layers form the metal gate stacks 156A-156D, as shown in FIGS. 3G, 4L, and 5L.

In some embodiments, the conductive filling does not extend into the recesses 144 since the recesses 144 are small and have been filled with other elements such as the gate dielectric layer 150 and the work function layer. However, embodiments of the disclosure are not limited thereto. In some other embodiments, a portion of the conductive filling extends into the recesses 144.

As shown in FIG. 3G, the semiconductor nanostructures 104a′-104d′ in the second region R2 are wider and thicker than the semiconductor nanostructures 104a′-104d′ in the first region R1, in accordance with some embodiments. As a result, a larger drive current may be achieved in the second region R2.

As shown in FIG. 3G, the semiconductor nanostructures 104a′-104d′ in the first region R1 are narrower and thinner than the semiconductor nanostructures 104a′-104d′ in the second region R2, in accordance with some embodiments. As a result, a better gate control and lower drain-induced barrier lowering (DIBL) may be achieved in the first region R1.

Many variations and/or modifications can be made to embodiments of the disclosure. In some embodiments, an over etching process is used during the formation of the semiconductor nanostructures 104a′-104d′, so as to fine-tune the profiles of the semiconductor nanostructures 104a′-104d′.

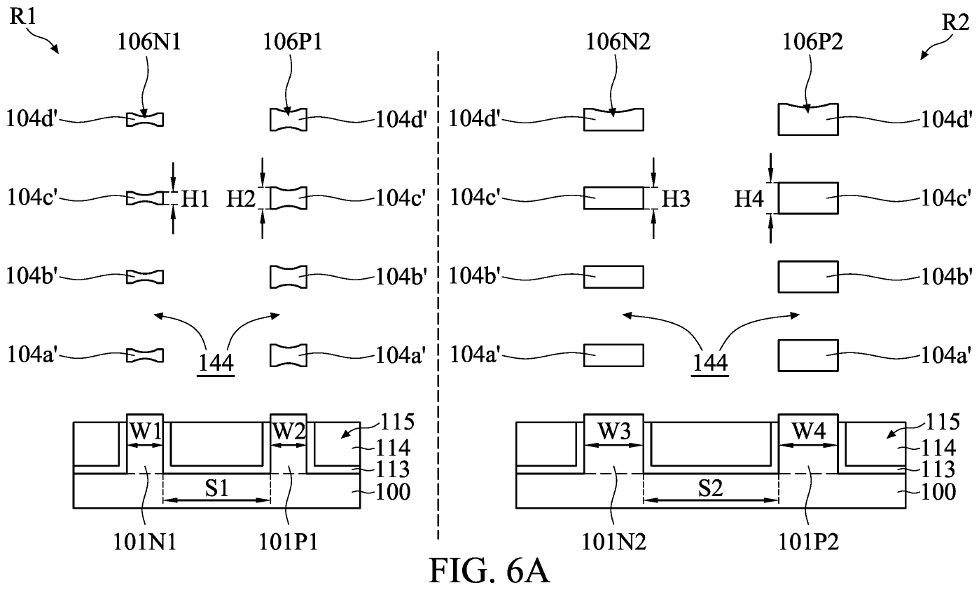

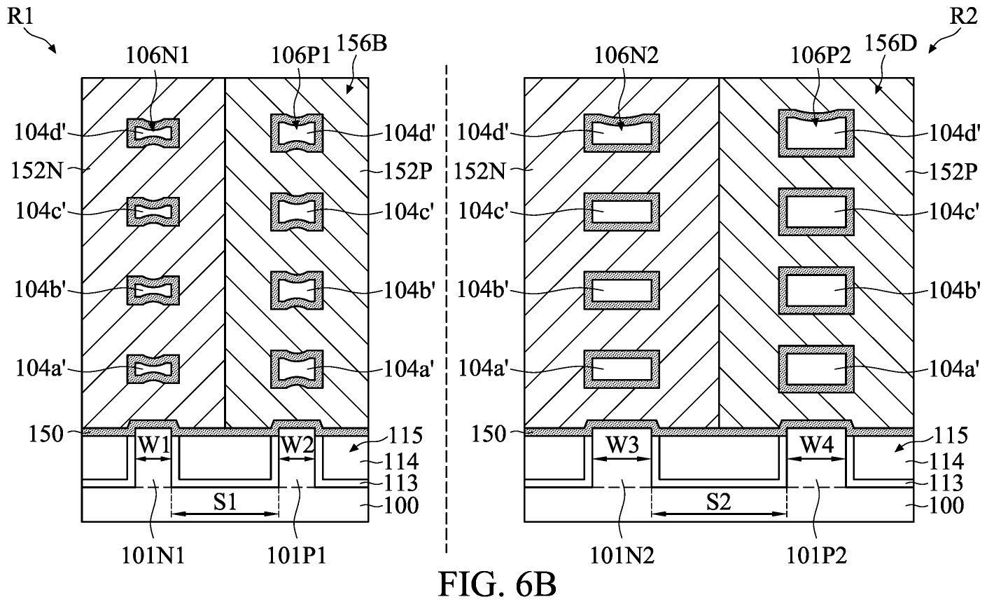

FIGS. 6A-6B are cross-sectional views of various stages of a process for forming portions of a semiconductor device structure, in accordance with some embodiments. As shown in FIG. 6A, a structure that is similar to the structure shown in FIG. 3F is formed, in accordance with some embodiments.

In some embodiments, an over etching process is used to remove the sacrificial layers 102a-102d. As mentioned above, in some embodiments, the semiconductor layers 104a-104d of a narrower fin structure (such as the fin structure 106N1 or 106P1) may be etched at a higher etching rate than a wider fin structure (such as the fin structure 106N2 or 106P2) during the formation of the semiconductor nanostructures 104a′-104d′. As a result, during the over etching process, the semiconductor layers 104a-104d of the fin structure 106N1 or 106P1 are etched at a higher etching rate. The semiconductor nanostructures 104a′-104d′ of the fin structures 106N1 and 106P1 thus have dumbbell-shaped profiles.

As shown in FIG. 6A, each of the semiconductor nanostructures 104a′-104d′ over the semiconductor fins 101N1 and 101P1 has an intermediate portion and edge portions. In some embodiments, the intermediate portion is thinner than each of the edge portions. In some embodiments, each of the semiconductor nanostructures 104a′-104d′ over the semiconductor fins 101N1 and 101P1 has a curved upper surface and a curved lower surface.

As shown in FIG. 6A, each of the semiconductor nanostructures 104a′-104c′ over the semiconductor fins 101N2 and 101P2 has a substantially planar upper surface and a substantially planar lower surface. In some embodiments, the uppermost semiconductor nanostructures (i.e., the semiconductor nanostructure 104d′) over the semiconductor fins 101N2 and 101P2 have a curved upper surface, which may be formed due to the removal of the dummy gate stacks 120C and 120D.

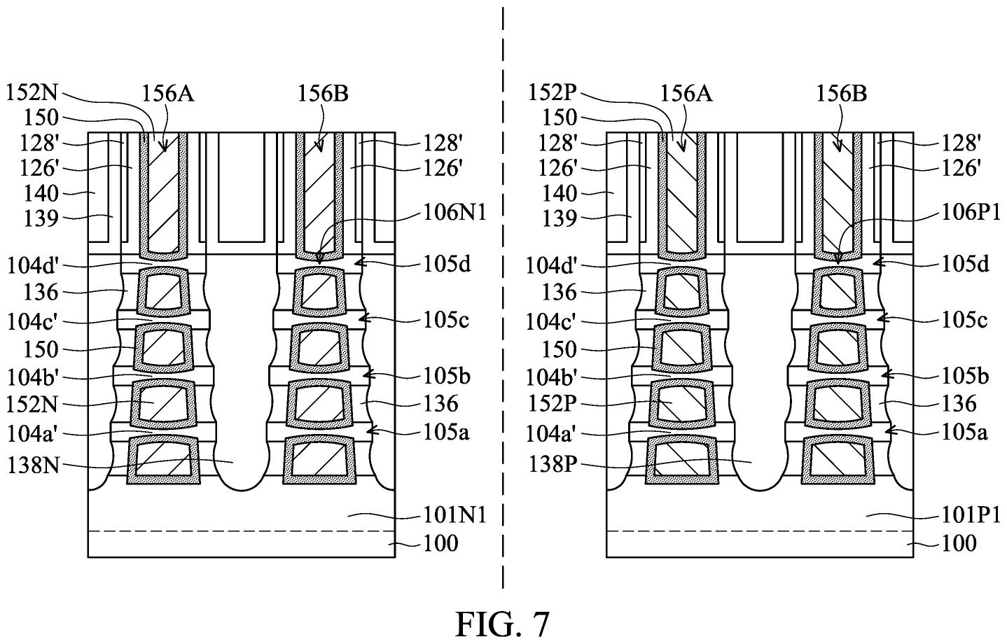

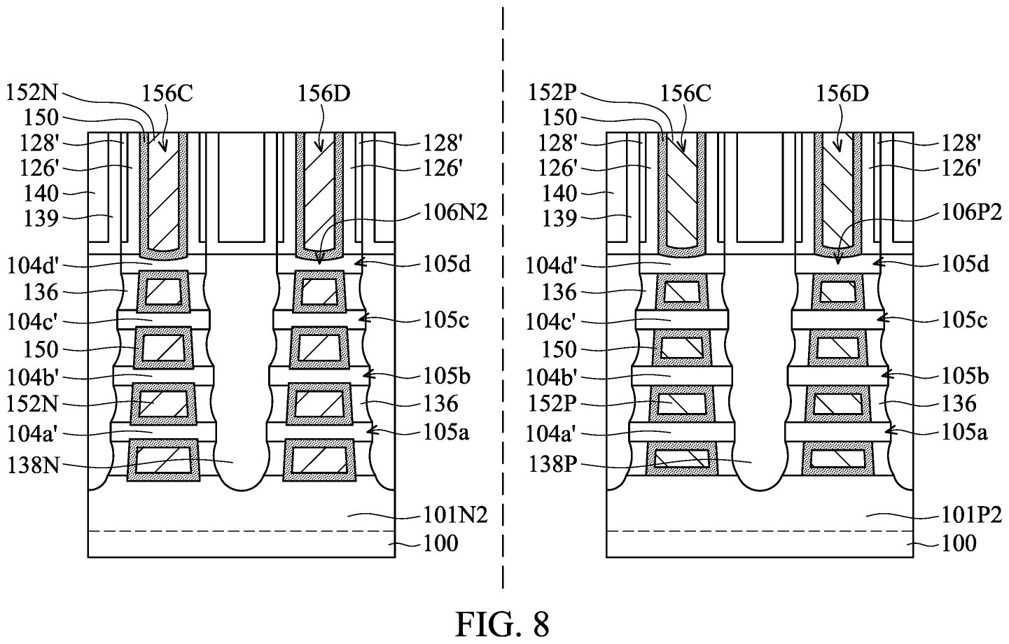

Afterwards, like the embodiments illustrated in FIG. 3G, metal gate stacks 156B and 156D are formed to be wrapped around the semiconductor nanostructures 104a′-104d′, as shown in FIG. 6B in accordance with some embodiments. FIG. 7 is a cross-sectional view of portions of a semiconductor device structure, in accordance with some embodiments. FIG. 8 is a cross-sectional view of portions of a semiconductor device structure, in accordance with some embodiments.

In some embodiments, FIG. 7 shows the cross-sectional view of a portion of the semiconductor device structure formed in the first region R1 of FIG. 6B. In some embodiments, FIG. 8 shows the cross-sectional view of a portion of the semiconductor device structure formed in the second region R2 of FIG. 6B.

As shown in FIGS. 6B and 7, due to the dumbbell-shaped profiles, the contact area between the metal gate stack 156B and the semiconductor nanostructures 104a′-104d′ of the fin structures 106N1 and 106P1 is enlarged. The gate control for the semiconductor device structures formed in the first region R1 is improved further.

As shown in FIGS. 6B and 8, the semiconductor nanostructures 104a′-104d′ of the fin structures 106N2 and 106P2 have a large cross-sectional area. In some embodiments, the upper surface and the lower surface of the semiconductor nanostructures 104a′-104c′ are substantially planar. A larger drive current may be achieved in the second region R2.

Embodiments of the disclosure form a semiconductor device structure with PMOS devices and NMOS devices. The PMOS devices and the NMOS devices are gate-all-around (GAA) transistor structures. Semiconductor nanostructures with different widths and different thicknesses may be simultaneously formed over selective areas, so as to form semiconductor devices with different functions. The performance and reliability of each of the semiconductor devices may be improved.

In accordance with some embodiments, a method for forming a semiconductor device structure is provided. The method includes forming a stack over a substrate, and the stack has multiple semiconductor layers and multiple sacrificial layers laid out in an alternating manner. The method also includes patterning the stack to form a first fin structure and a second fin structure, and the second fin structure is wider than the first fin structure. The method further includes forming a first gate stack wrapped around the first fin structure and forming a second gate stack wrapped around the second fin structure. In addition, the method includes simultaneously removing the sacrificial layers of the first fin structure and the second fin structure. Remaining portions of the semiconductor layers of the first fin structure form multiple first semiconductor nanostructures, and remaining portions of the semiconductor layers of the second fin structure form multiple second semiconductor nanostructures. Each of the second semiconductor nanostructures is thicker than each of the first semiconductor nanostructures.

In accordance with some embodiments, a method for forming a semiconductor device structure is provided. The method includes forming a first fin structure and a second fin structure over a substrate. Each of the first fin structure and the second fin structure has multiple sacrificial layers and multiple semiconductor layers laid out in an alternating manner, and the first fin structure is substantially as wide as the second fin structure. The method also includes forming a gate stack wrapped around the first fin structure and the second fin structure. The method further includes simultaneously removing the sacrificial layers of the first fin structure and the second fin structure. Remaining portions of the semiconductor layers of the first fin structure form multiple first semiconductor nanostructures, and remaining portions of the semiconductor layers of the second fin structure form multiple second semiconductor nanostructures. Each of the first semiconductor nanostructures is thicker than each of the second semiconductor nanostructures.

In accordance with some embodiments, a semiconductor device structure is provided. The semiconductor device structure includes multiple first semiconductor nanostructures and a first gate stack wrapped around each of the first semiconductor nanostructures. Each of the first semiconductor nanostructures has a first width measured along a long extension direction of the first gate stack. The semiconductor device structure also includes multiple second semiconductor nanostructures and a second gate stack wrapped around each of the second semiconductor nanostructures. Each of the second semiconductor nanostructures has a second width measured along a long extension direction of the second gate stack, and the second width is wider than the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a stack over a substrate, wherein the stack has a plurality of semiconductor layers and a plurality of sacrificial layers laid out in an alternating manner;
patterning the stack to form a first fin structure and a second fin structure, wherein the second fin structure is wider than the first fin structure;
forming a first gate stack wrapped around the first fin structure;
forming a second gate stack wrapped around the second fin structure; and
simultaneously removing the sacrificial layers of the first fin structure and the second fin structure, wherein remaining portions of the semiconductor layers of the first fin structure form a plurality of first semiconductor nanostructures, remaining portions of the semiconductor layers of the second fin structure form a plurality of second semiconductor nanostructures, and each of the second semiconductor nanostructures is thicker than each of the first semiconductor nanostructures.

2. The method for forming a semiconductor device structure as claimed in claim 1, further comprising:
partially removing the first fin structure and the second fin structure to form a plurality of recesses exposing side surfaces of the semiconductor layers and the sacrificial layers of the first fin structure and the second fin structure;
forming a plurality of inner spacers covering the side surfaces of the sacrificial layers of the first fin structure and the second fin structure;
forming first epitaxial structures on the side surfaces of the semiconductor layers of the first fin structure before the first semiconductor nanostructures are formed; and
forming second epitaxial structures on the side surfaces of the semiconductor layers of the second fin structure before the second semiconductor nanostructures are formed, wherein the first epitaxial structures and the second epitaxial structures have a same conductivity type.

3. The method for forming a semiconductor device structure as claimed in claim 1, wherein a third fin structure is formed during the patterning of the stack, the third fin structure is substantially as wide as the first fin structure, and the first gate stack is wrapped around the third fin structure, and the method further comprises:
removing the sacrificial layers of the third fin structure, wherein remaining portions of the semiconductor layers of the third fin structure form a plurality of third semiconductor nanostructures, and each of the first semiconductor nanostructures is thicker than each of the third semiconductor nanostructures.

4. The method for forming a semiconductor device structure as claimed in claim 3, further comprising:
partially removing the first fin structure and the third fin structure to form a plurality of recesses exposing side surfaces of the semiconductor layers and the sacrificial layers of the first fin structure and the third fin structure;
forming a plurality of inner spacers covering the side surfaces of the sacrificial layers of the first fin structure and the third fin structure;
forming p-type doped epitaxial structures on the side surfaces of the semiconductor layers of the first fin structure before the first semiconductor nanostructures are formed; and
forming n-type doped epitaxial structures on the side surfaces of the semiconductor layers of the third fin structure before the third semiconductor nanostructures are formed.

5. The method for forming a semiconductor device structure as claimed in claim 3, wherein a fourth fin structure is formed during the patterning of the stack, the fourth fin structure is substantially as wide as the second fin structure, and the second gate stack is wrapped around the fourth fin structure, and the method further comprises:
removing the sacrificial layers of the fourth fin structure, wherein remaining portions of the semiconductor layers of the fourth fin structure form a plurality of fourth semiconductor nanostructures, each of the second semiconductor nanostructures is thicker than each of the fourth semiconductor nanostructures, and each of the fourth semiconductor nanostructures is thicker than each of the third semiconductor nanostructures.

6. The method for forming a semiconductor device structure as claimed in claim 5, wherein the first semiconductor nanostructures, the second semiconductor nanostructures, the third semiconductor nanostructures, and the fourth semiconductor nanostructures are formed simultaneously.

7. The method for forming a semiconductor device structure as claimed in claim 6, wherein each of the second semiconductor nanostructures has a substantially planar upper surface and a substantially planar lower surface.

8. The method for forming a semiconductor device structure as claimed in claim 6, wherein each of the first semiconductor nanostructures and the third semiconductor nanostructures has a curved upper surface and a curved lower surface.

9. The method for forming a semiconductor device structure as claimed in claim 6, further comprising:
removing the first gate stack and the second gate stack before the first semiconductor nanostructures, the second semiconductor nanostructures, the third semiconductor nanostructures, and the fourth semiconductor nanostructures are formed;
forming a first metal gate stack wrapped around the first semiconductor nanostructures and the third semiconductor nanostructures; and
forming a second metal gate stack wrapped around the second semiconductor nanostructures and the fourth semiconductor nanostructures.

10. The method for forming a semiconductor device structure as claimed in claim 9, wherein the first metal gate stack has a first p-type work function layer wrapped around each of the first semiconductor nanostructures, the second metal gate stack has a second p-type work function layer wrapped around each of the second semiconductor nanostructures, the first metal gate stack has a first n-type work function layer wrapped around each of the third semiconductor nanostructures, and the second metal gate stack has a second n-type work function layer wrapped around each of the fourth semiconductor nanostructures.

11. A method for forming a semiconductor device structure, comprising:
forming a first fin structure and a second fin structure over a substrate, wherein each of the first fin structure and the second fin structure has a plurality of sacrificial layers and a plurality of semiconductor layers laid out in an alternating manner, and the first fin structure is substantially as wide as the second fin structure;
forming a gate stack wrapped around the first fin structure and the second fin structure; and
simultaneously removing the sacrificial layers of the first fin structure and the second fin structure, wherein remaining portions of the semiconductor layers of the first fin structure form a plurality of first semiconductor nanostructures, remaining portions of the semiconductor layers of the second fin structure form a plurality of second semiconductor nanostructures, and each of the first semiconductor nanostructures is thicker than each of the second semiconductor nanostructures.

12. The method for forming a semiconductor device structure as claimed in claim 11, further comprising:
partially removing the first fin structure and the second fin structure to form a plurality of recesses exposing side surfaces of the semiconductor layers and the sacrificial layers of the first fin structure and the second fin structure;
forming a plurality of inner spacers covering the side surfaces of the sacrificial layers of the first fin structure and the second fin structure;
forming p-type doped epitaxial structures on the side surfaces of the semiconductor layers of the first fin structure before the first semiconductor nanostructures are formed; and
forming n-type doped epitaxial structures on the side surfaces of the semiconductor layers of the second fin structure before the second semiconductor nanostructures are formed.

13. The method for forming a semiconductor device structure as claimed in claim 11, further comprising:
forming a third fin structure and a fourth fin structure over a substrate, wherein each of the third fin structure and the fourth fin structure has a plurality of second sacrificial layers and a plurality of second semiconductor layers laid out in an alternating manner, the third fin structure is substantially as wide as the fourth fin structure, and the third fin structure is wider than the first fin structure;
forming a second gate stack wrapped around the third fin structure and the fourth fin structure; and
simultaneously removing the second sacrificial layers of the third fin structure and the fourth fin structure, wherein remaining portions of the second semiconductor layers of the third fin structure form a plurality of third semiconductor nanostructures, remaining portions of the second semiconductor layers of the fourth fin structure form a plurality of fourth semiconductor nanostructures, each of the third semiconductor nanostructures is thicker than each of the fourth semiconductor nanostructures, and each of the fourth semiconductor nanostructures is thicker than each of the second semiconductor nanostructures.

14. The method for forming a semiconductor device structure as claimed in claim 13, wherein the first semiconductor nanostructures, the second semiconductor nanostructures, the third semiconductor nanostructures, and the fourth semiconductor nanostructures are formed simultaneously.

15. The method for forming a semiconductor device structure as claimed in claim 14, wherein each of the third semiconductor nanostructures and the fourth semiconductor nanostructures has a substantially planar upper surface and a substantially planar lower surface, and each of the first semiconductor nanostructures and the second semiconductor nanostructures has a dumbbell-shaped profile.

16. A semiconductor device structure, comprising:
a plurality of first semiconductor nanostructures;
a first gate stack wrapped around each of the first semiconductor nanostructures, wherein each of the first semiconductor nanostructures has a first width measured along a long extension direction of the first gate stack;
a plurality of second semiconductor nanostructures; and
a second gate stack wrapped around each of the second semiconductor nanostructures, wherein each of the second semiconductor nanostructures has a second width measured along a long extension direction of the second gate stack, and the second width is wider than the first width.

17. The semiconductor device structure as claimed in claim 16, wherein each of the second semiconductor nanostructures is thicker than each of the first semiconductor nanostructures.

18. The semiconductor device structure as claimed in claim 16, further comprising:
a plurality of third semiconductor nanostructures, wherein the first gate stack is wrapped around each of the third semiconductor nanostructures, each of the third semiconductor nanostructures has a third width measured along the long extension direction of the first gate stack, the third width is substantially equal to the first width, and each of the first semiconductor nanostructures is thicker than each of the third semiconductor nanostructures;
a p-type doped epitaxial structure adjacent to the first semiconductor nanostructures; and
an n-type doped epitaxial structure adjacent to the third semiconductor nanostructures.

19. The semiconductor device structure as claimed in claim 18, further comprising:
a plurality of fourth semiconductor nanostructures, wherein the second gate stack is wrapped around each of the fourth semiconductor nanostructures, each of the fourth semiconductor nanostructures has a fourth width measured along the long extension direction of the second gate stack, the fourth width is substantially equal to the second width, each of the second semiconductor nanostructures is thicker than each of the fourth semiconductor nanostructures, and each of the fourth semiconductor nanostructures is thicker than each of the third semiconductor nanostructures;
a second p-type doped epitaxial structure adjacent to the second semiconductor nanostructures; and
a second n-type doped epitaxial structure adjacent to the fourth semiconductor nanostructures.

20. The semiconductor device structure as claimed in claim 18, wherein each of the third semiconductor nanostructures has an intermediate portion and edge portions, and the intermediate portion is thinner than each of the edge portions.
